(19) United States
(12) Patent Application Publication
(10) Pub. No.: US 2021/0261843 A1
(43) Pub. Date: Aug. 26, 2021

(54) HEAT STORAGE SHEET, HEAT STORAGE MEMBER, ELECTRONIC DEVICE, AND MANUFACTURING METHOD OF HEAT STORAGE SHEET

(71) Applicant: FUJIFILM Corporation, Tokyo (JP)

(72) Inventors: Hiroshi KAWAKAMI, Shizuoka (JP); Masahiro HATTA, Shizuoka (JP); Tetsuro MITSUI, Shizuoka (JP); Aya NAKAYAMA, Shizuoka (JP); Takuto MATSUSHITA, Shizuoka (JP)

(73) Assignee: FUJIFILM Corporation, Tokyo (JP)

(21) Appl. No.: 17/319,055

(22) Filed: May 12, 2021

Related U.S. Application Data
(63) Continuation of application No. PCT/JP2019/043861, filed on Nov. 8, 2019.

(30) Foreign Application Priority Data
Nov. 26, 2018 (JP) 2018-220569
Feb. 28, 2019 (JP) 2019-036983
Mar. 25, 2019 (JP) 2019-057347
Sep. 2, 2019 (JP) 2019-159485

(51) Int. Cl. C09K 5/06; C08L 29/04; C08L 75/04; B01J 13/16

(52) U.S. Cl. CPC C09K 5/063; B01J 13/16; C08L 75/04; C08L 29/04

(57) ABSTRACT

The present invention provides a heat storage sheet which exhibits an excellent heat storage property, a heat storage member, an electronic device, and a manufacturing method of a heat storage sheet. The heat storage sheet according to an embodiment of the present invention is a heat storage sheet including a heat storage material, and a microcapsule which encapsulates at least a part of the heat storage material, in which a content ratio of the heat storage material to a total mass of the heat storage sheet is 65% by mass or more.

### CROSS-REFERENCE TO RELATED APPLICATIONS

This application is a Continuation of PCT International Application No. PCT/JP2019/043861 filed on Nov. 8, 2019, which claims priority under 35 U.S.C. § 119(a) to Japanese Patent Application No. 2018-220569 filed on Nov. 26, 2018, Japanese Patent Application No. 2019-036983 filed on Feb. 28, 2019, Japanese Patent Application No. 2019-057347 filed on Mar. 25, 2019 and Japanese Patent Application No. 2019-159485 filed on Sep. 2, 2019. Each of the above applications is hereby expressly incorporated by reference, in its entirety, into the present application.

### BACKGROUND OF THE INVENTION

### 1. Field of the Invention

The present disclosure relates to a heat storage sheet, a heat storage member, an electronic device, and a manufacturing method of a heat storage sheet.

### 2. Description of the Related Art

In recent years, a microcapsule has attracted attention because there is a possibility that new value can be provided to customers by encapsulating and protecting functional materials such as a fragrance, a dye, a heat storage material, and a pharmaceutical component.

For example, a microcapsule which includes paraffins or the like as a phase change material (PCM) has been known. Specifically, a heat storage acrylic resin sheet-shaped formed body formed by using the microcapsule which encapsulates the heat storage material is disclosed (see, for example, JP2009-029985A). Further, a heat storage sheet-shaped formed body obtained by forming and hardening a heat storage acrylic resin composition, which contains a predetermined amount of the microcapsule which encapsulates the heat storage material, into a sheet shape is disclosed (see, for example, JP2007-031610A).

### SUMMARY OF THE INVENTION

However, in the inventions disclosed in JP2009-029985A and JP2007-031610A, the amount of microcapsules included in the sheet-shaped formed body and a presence amount of the heat storage materials have not reached a satisfactory amount, and a material which has a larger latent heat capacity is required to control the amount of heat or utilize heat of a heat generating body which generates heat.

The present disclosure has been made in view of the above circumstances.

An object to be solved by embodiments of the present disclosure is to provide a heat storage sheet which exhibits an excellent heat storage property.

Further, another object to be solved by the embodiments of the present disclosure is to provide a heat storage member, an electronic device, and a manufacturing method of a heat storage sheet.

Specific means for solving the objects include the aspects as follows.

(1) A heat storage sheet comprising a heat storage material, and a microcapsule which encapsulates at least a part of the heat storage material, in which a content ratio of the heat storage material to a total mass of the heat storage sheet is 65% by mass or more.

(2) The heat storage sheet according to (1), further comprising a binder.

(3) The heat storage sheet according to (2), in which the binder is a water-soluble polymer.

(4) The heat storage sheet according to (3), in which the water-soluble polymer is polyvinyl alcohol.

(5) The heat storage sheet according to any one of (2) to (4), in which a content ratio of the binder to a total mass of the microcapsule is 15% by mass or less.

(6) The heat storage sheet according to any one of (1) to (5), in which the heat storage material includes a latent heat storage material.

(7) The heat storage sheet according to any one of (1) to (6), in which a content ratio of the microcapsule to the total mass of the heat storage sheet is 75% by mass or more.

(8) The heat storage sheet according to any one of (1) to (7), in which a mass of a capsule wall of the microcapsule to a mass of the heat storage material is 12% by mass or less.

(9) The heat storage sheet according to any one of (1) to (8), in which a capsule wall of the microcapsule includes at least one selected from the group consisting of polyurethane urea, polyurethane, and polyuria.

(10) The heat storage sheet according to any one of (1) to (9), in which the microcapsule satisfies a relationship of Expression (1).

δ/Dm≤0.010 Expression (1)

Where, δ represents a thickness (μm) of a capsule wall of the microcapsule. Dm represents a volume-based median diameter (μm) of the microcapsule.

(11) The heat storage sheet according to any one of (1) to (10), in which a void volume is 15% by volume or less.

(12) The heat storage sheet according to any one of (1) to (11), in which the content ratio of the heat storage material to the total mass of the heat storage sheet is 80% by mass or more.

(13) The heat storage sheet according to any one of (1) to (12), further comprising a thermal conductive material.

(14) The heat storage sheet according to (13), in which a content ratio of the thermal conductive material to the total mass of the heat storage sheet is 2% by mass or more.

(15) The heat storage sheet according to (13) or (14), in which a thermal conductivity of the thermal conductive material is 50 Wm⁻¹K⁻¹ or more.

(16) The heat storage sheet according to any one of (1) to (15), in which a content of a linear aliphatic hydrocarbon having a melting point of 0° C. or higher to a total mass of the heat storage material is 98% by mass or more.

(17) The heat storage sheet according to any one of (1) to (16), in which a latent heat capacity is 135 J/ml or more.

(18) The heat storage sheet according to any one of (1) to (17), in which a latent heat capacity is 160 J/g or more.

(19) A heat storage member comprising the heat storage sheet according to any one of (1) to (18), and a base material.

(20) The heat storage member according to (19), further comprising an adhesion layer which is provided on a side of the base material opposite to a side provided with the heat storage sheet.

(21) The heat storage member according to (19) or (20), further comprising an easily adhesive layer which is provided between the base material and the heat storage sheet.

(22) The heat storage member according to any one of (19) to (21), further comprising a protective layer.

(23) The heat storage member according to any one of (19) to (22), in which a thickness of the heat storage sheet to a thickness of the heat storage member is 80% or more.

(24) An electronic device comprising the heat storage sheet according to any one of (1) to (18), or the heat storage member according to any one of (19) to (23).

(25) The electronic device according to (24), further comprising a heat generating body.

(26) A manufacturing method of a heat storage sheet, the method comprising a step of mixing a heat storage material, polyisocyanate, at least one active hydrogen-containing compound selected from the group consisting of polyol and polyamine, and an emulsifier to produce a dispersion liquid including a microcapsule which encapsulates at least a part of the heat storage material, and a step of manufacturing a heat storage sheet by using the dispersion liquid without substantially adding a binder to the dispersion liquid.

(27) The manufacturing method of a heat storage sheet according to (26), in which the microcapsule satisfies a relationship of Expression (1).

δ/Dm≤0.010 Expression (1)

Where, δ represents a thickness (μm) of a capsule wall of the microcapsule. Dm represents a volume-based median diameter (μm) of the microcapsule.

(28) The manufacturing method of a heat storage sheet according to (26) or (27), in which the emulsifier is able to be bonded to the polyisocyanate.

According to the embodiments of the present disclosure, a heat storage sheet which exhibits an excellent heat storage property, a heat storage member, an electronic device, and a manufacturing method of a heat storage sheet are provided.

### DESCRIPTION OF THE PREFERRED EMBODIMENTS

Hereinafter, a heat storage sheet and a heat storage member according to the present disclosure will be described in detail.

Note that the description of the configuration elements according to the embodiments of the present disclosure is based on the typical embodiment of the present disclosure, but the present disclosure is not limited to such embodiments.

In the present specification, the numerical range represented by “to” denotes a range including numerical values described before and after “to” as a minimum value and a maximum value, respectively. In the numerical range described stepwise in the present disclosure, an upper limit value or a lower limit value described in a certain numerical range may be replaced with an upper limit value or a lower limit value of another numerical range described stepwise. Further, in the numerical range described in the present disclosure, the upper limit value or the lower limit value described in a certain numerical range may be replaced with a value shown in Examples.

In the numerical range described stepwise in the present specification, an upper limit value or a lower limit value described in a numerical range may be replaced with an upper limit value or a lower limit value of another numerical range described stepwise. Further, in the numerical range described in the present specification, the upper limit value or the lower limit value in the numerical range may be replaced with a value shown in Examples.

Furthermore, in the present disclosure, “% by mass” and “% by weight” are synonymous, and “parts by mass” and “parts by weight” are synonymous.

Furthermore, in the present disclosure, a combination of two or more preferred embodiments is a more preferred embodiment.

In the present disclosure, an amount of each component in a composition or a layer is a total amount of a plurality of substances present in the composition unless otherwise noted, in a case in which a plurality of substances corresponding to each component are present in the composition.

<Heat Storage Sheet>

A heat storage sheet according to the present disclosure is a heat storage sheet including a heat storage material, and a microcapsule which encapsulates at least a part of the heat storage material, in which a content ratio of the heat storage material to a total mass of the heat storage sheet is 65% by mass or more.

In the related art, as disclosed in JP2009-029985A and JP2007-031610A, a sheet having a heat storage property, which includes a microcapsule, has been proposed. However, in recent years, smartphones have become smaller and thinner, and with the installation of a dustproof function or a waterproof function, there is a demand for a heat storage sheet which can store a larger amount of heat than the related art.

The heat storage sheet according to the present disclosure exhibits a heat storage function by transferring of heat due to a phase change between a solid and a liquid of the heat storage material included in the heat storage sheet (in particular, the heat storage material included in a core portion of the microcapsule). Therefore, for example, it is possible to absorb and radiate heat in a heat generating body which generates heat. The heat storage sheet according to the present disclosure exhibits a more excellent heat storage function by having a structure in which the presence amount of the heat storage materials, which could not be achieved in the related art, is significantly increased as compared with the related art. Therefore, it possible to provide the heat storage sheet which can store a larger amount of heat than the related art.

Further, in a case in which a latent heat storage material is used as the heat storage material, for example, the heat storage material can absorb and radiate heat in the heat generating body as the latent heat.

As will be described below, a manufacturing method of a heat storage sheet according to the present disclosure is not particularly limited. For example, in a case of manufacturing a predetermined heat storage sheet, the heat storage sheet is manufactured without adding a binder to a dispersion liquid of the microcapsule, and a content ratio of the microcapsule in the heat storage sheet can be increased, and as a result, the content ratio of the heat storage material in the heat storage sheet can be increased. That is, by decreasing the amount of the binder in the heat storage sheet, the content ratio of the heat storage material in the heat storage sheet can be increased.

Further, by thinning the wall thickness of the capsule wall of the microcapsule (stated another way, reducing a mass ratio of the capsule wall in the microcapsule), the content ratio of the heat storage material in the heat storage sheet can be increased.

As described above, in the present invention, by decreasing the amount of the binder in the heat storage sheet and thinning the wall thickness of the capsule wall of the microcapsule, a more effective heat storage sheet is obtained.

[Microcapsule]

The microcapsule according to the present disclosure has a core portion and a wall portion for encapsulating a core material (encapsulated material (also referred to as an encapsulating component)) which forms the core portion, and the wall portion is also referred to as a “capsule wall”.

[[Core Material]]

The microcapsule according to the present disclosure encapsulates the heat storage material as the core material (encapsulating component).

Since at least a part of the heat storage material is present by being encapsulated in the microcapsule, the heat storage material can be stably present in a phase state depending on the temperature.

—Heat Storage Material—

The heat storage material can be appropriately selected from materials which can repeat the phase change between the solid phase and the liquid phase due to the state change of melting and solidification depending on the temperature change, depending on a target (for example, the heat generating body) or a purpose of heat amount control or heat utilization, or the like.

It is preferable that the phase change of the heat storage material be based on the melting point of the heat storage material itself.

As the heat storage material, for example, any of a material which can store heat which is generated outside the heat storage sheet as sensible heat or a material (hereinafter, also referred to as a “latent heat storage material”) which can store heat which is generated outside the heat storage sheet as latent heat may be adopted. It is preferable that the heat storage material be a material which can radiate the stored heat.

Above all, it is preferable that the heat storage material be the latent heat storage material, from the viewpoint of the control of the amount of heat which can be transferred, the control speed of heat, and the magnitude of the amount of heat.

(Latent Heat Storage Material)

The latent heat storage material means a material which stores heat, which is generated outside the heat storage sheet, as latent heat, and transfers heat due to latent heat by repeating the change between melting and solidification with the melting point determined by the material as a phase change temperature.

The latent heat storage material can utilize the heat of fusion at the melting point and the heat of solidification at a solidifying point, store heat depending on the phase change between the solid and the liquid, and radiate heat.

The latent heat storage material can be selected from compounds having a melting point and capable of changing a phase.

Examples of the latent heat storage material include ice (water); an aliphatic hydrocarbon such as paraffin (for example, isoparaffin and normal paraffin) and the like; an inorganic salt; an organic acid ester compound such as caprylic/capric triglyceride, methyl myristate (melting point of 16° C. to 19° C.), isopropyl myristate (melting point of 167° C.), and dibutyl phthalate (melting point of −35° C.); an aromatic hydrocarbon such as an alkylnaphthalene compound such as diisopropylnaphthalene (melting point of 67° C. to 70° C.), a diarylalkane compound such as 1-phenyl-1-xylylethane (melting point lower than −50° C.), an alkylbiphenyl compound such as 4-isopropylbiphenyl (melting point of 11° C.), a triarylmethane compound, an alkylbenzene compound, a benzylnaphthalene compound, a diarylalkylene compound, and an aryl indane compound; natural animal and plant oils such as camellia oil, soybean oil, corn oil, cotton seed oil, rapeseed oil, olive oil, coconut oil, castor oil, and fish oil; and high boiling point distillates of natural products such as mineral oil.

Among the latent heat storage materials, paraffin is preferable from the viewpoint of exhibiting the excellent heat storage property.

As the paraffin, a linear aliphatic hydrocarbon having a melting point of 0° C. or higher is preferable, and a linear aliphatic hydrocarbon having a melting point of 0° C. or higher and having 14 or more carbon atoms is more preferable.

Examples of the linear aliphatic hydrocarbon having the melting point of 0° C. or higher include n-tetradecane (melting point of 6° C.), n-pentadecane (melting point of 10° C.), n-hexadecane (melting point of 18° C.), n-heptadecane (melting point of 22° C.), n-octadecane (melting point of 28° C.), n-nonadecane (melting point of 32° C.), n-icosane (melting point of 37° C.), n-henicosane (melting point of 40° C.), n-docosane (melting point of 44° C.), n-tricosane (melting point of 48° C. to 50° C.), n-tetracosane (melting point of 52° C.), n-pentacosane (melting point of 53° C. to 56° C.), n-hexacosane (melting point of 55° C. to 58° C.), n-heptacosane (melting point of 60° C.), n-octacosane (melting point of 62° C.), n-nonacosane (melting point of 63° C. to 66° C.), n-triacontane (melting point of 66° C.), and the like. Among these, n-heptadecane (melting point of 22° C.), n-octadecane (melting point of 28° C.), n-nonadecane (melting point of 32° C.), n-icosane (melting point of 37° C.), n-henicosane (melting point of 40° C.), n-docosane (melting point of 44° C.), n-tricosane (melting point of 48° C. to 50° C.), n-tetracosane (melting point of 52° C.), n-pentacosane (melting point of 53° C. to 56° C.), n-hexacosane (melting point of 60° C.), n-heptacosane (melting point of 60° C.), or n-octacosane (melting point of 62° C.) is preferably used.

In a case in which a linear aliphatic hydrocarbon having the melting point of 0° C. or higher is used as the heat storage material, the content of the linear aliphatic hydrocarbon having the melting point of 0° C. or higher to the content of the heat storage material is preferably 80% by mass or more, more preferably 90% by mass or more, further preferably 95% by mass or more, and particularly preferably 98% by mass or more. For example, an upper limit is 100% by mass.

As the inorganic salt, an inorganic hydrated salt is preferable, and the examples thereof include alkali metal chloride hydrate (for example, sodium chloride dihydrate), alkali metal acetate hydrate (for example, sodium acetate hydrate), alkali metal sulfate hydrate (for example, sodium sulfate hydrate), alkali metal thiosulfate hydrate (for example, sodium thiosulfate hydrate), alkaline earth metal sulfate hydrate (for example, calcium sulfate hydrate), alkaline earth metal chloride hydrate (for example, calcium chloride hydrate), and the like.

The melting point of the heat storage material need only be selected depending on the type of the heat generating body which generates heat, a heat generating temperature of the heat generating body, a temperature or a maintaining temperature after cooling, the purpose of a cooling method, and the like. By appropriately selecting the melting point, for example, the temperature of the heat generating body which generates heat can be stably maintained at an appropriate temperature which does not overcool.

It is preferable that the heat storage material be selected mainly from a material having the melting point at a center temperature of a target temperature range (for example, an operating temperature of the heat generating body; hereinafter, also referred to as a “heat control range”).

The selection of the heat storage material can be performed depending on the melting point of the heat storage material for the heat control range. The heat control range is set depending on the application (for example, the type of heat generating body).

Specifically, the melting point of the heat storage material to be selected differs depending on the heat control range, but the material having the following melting points can be suitably selected as the heat storage material, for example. It is suitable in a case in which the application is, for example, an electronic device (in particular, a small or portable handy electronic device).

(1) Among the heat storage materials described above (preferably, the latent heat storage material), the heat storage material having the melting point of 0° C. or higher and 80° C. or lower is preferable.

In a case in which the heat storage material having the melting point of 0° C. or higher and 80° C. or lower is used, the material having the melting point lower than 0° C. or higher than 80° C. is not included in the heat storage material. Among the materials having the melting point lower than 0° C. or higher than 80° C., the material in a liquid state may be used in combination with the heat storage material as a solvent.

(2) Among the above, the heat storage material having the melting point of 10° C. or higher and 70° C. or lower is preferable.

In a case in which the heat storage material having the melting point of 10° C. or higher and 70° C. or lower is used, the material having the melting point lower than 10° C. or higher than 70° C. is not included in the heat storage material. Among the materials having the melting point lower than 10° C. or higher than 70° C., the material in the liquid state may be used in combination with the heat storage material as the solvent.

(3) Further, the heat storage material having the melting point of 15° C. or higher and 50° C. or lower is preferable.

In a case in which the heat storage material having the melting point of 15° C. or higher and 50° C. or lower is used, the material having the melting point lower than 15° C. or higher than 50° C. is not included in the heat storage material. Among the materials having the melting point lower than 15° C. or higher than 50° C., the material in the liquid state may be used in combination with the heat storage material as the solvent.

(4) Further, in the above (2), the heat storage material having the melting point of 20° C. to 62° C. is also preferable.

In particular, the heat generating body of the electronic device, such as a thin or portable laptop computer, a tablet, and a smartphone, has the operating temperature of 20° C. to 65° C. in many cases, and it is suitable to use the heat storage material having the melting point of 20° C. to 62° C. In a case in which the heat storage material having the melting point of 20° C. to 62° C. is used, the material having the melting point lower than 20° C. or higher than 62° C. is not included in the heat storage material. Among the materials having the melting point lower than 20° C. or higher than 62° C., the material in the liquid state may be used in combination with the heat storage material as the solvent, but it is preferable that the solvent be substantially excluded in terms of absorbing a large amount of heat which is generated by the heat generating body.

The heat storage material may be included alone or may be included in a combination of a plurality of types. By using the heat storage material alone or a plurality of types of heat storage materials having different melting points, the temperature range in which the heat storage property is exhibited and the amount of heat storage can be adjusted depending on the application.

The temperature range in which heat can be stored can be expanded by mixing the heat storage material, as a center material, having the melting point at the center temperature at which the heat storage effect of the heat storage material is desired, and the heat storage material having the melting point before and after the center temperature. An example of a case in which the paraffin is used as the heat storage material will be specifically described. Paraffin a having the melting point at the center temperature at which the heat storage effect of the heat storage material is desired is used as a center material, and the paraffin a and another paraffin having the carbon atoms before and after the paraffin a are mixed, so that the material can be designed to have a wide temperature range (heat control range). The content ratio of paraffin having the melting point at the center temperature at which the heat storage effect is desired to the total mass of the heat storage material is preferably 80% by mass or more, more preferably 90% by mass or more, and further preferably 95% by mass or more.

In a case in which the paraffin is used as the latent heat storage material according to the present disclosure, for example, the paraffin may be used alone or may be used in the combination of two types or more. In a case in which a plurality of paraffins having different melting points are used, the temperature range in which the heat storage property is exhibited can be widened.

In a case in which the plurality of paraffins are used, a mixture including only linear paraffin and substantially excluding branched chain paraffin is desirable in order not to reduce the endothermic property. Where, substantially excluding the branched chain paraffin means that the content of the branched chain paraffin to the total mass of the paraffin is 5% by mass or less, and it is preferably 2% by mass or less, and further preferably 1% by mass or less. From the viewpoints of the temperature range in which the heat storage property is exhibited and the amount of heat storage, the content ratio of the main paraffin to the total mass of the paraffin is preferably 80% by mass to 100% by mass, more preferably 90% by mass to 100% by mass, and further preferably 95% by mass to 100% by mass. The “main paraffin” refers to the paraffin having the largest content among the plurality of paraffins which are contained. It is preferable that the content of the main paraffin to the total amount of the plurality of paraffins be 50% by mass or more.

The content ratio of the paraffin to the total mass of the heat storage material (preferably, latent heat storage material) is preferably 80% by mass to 100% by mass, more preferably 90% by mass to 100% by mass, and further preferably 95% by mass to 100% by mass.

The heat storage sheet according to the present disclosure includes at least the heat storage material which is encapsulated in the microcapsule, but the heat storage material may be present outside the microcapsule. That is, the heat storage sheet according to the present disclosure may include the heat storage material which is encapsulated in the microcapsule, and the heat storage material which is present inside the heat storage sheet and outside the microcapsule. In this case, it is preferable that 95% by mass or more of the heat storage material be encapsulated in the microcapsule based on the total mass of the heat storage material included in the heat storage sheet. That is, the content ratio (encapsulation ratio) of the heat storage material which is encapsulated in the microcapsule is preferably 95% by mass or more based on the total mass of the heat storage material included in the heat storage sheet. The upper limit is not particularly limited, but 100% by mass can be adopted, for example.

As the heat storage material in the heat storage sheet, 95% by mass or more of the heat storage material based on the total mass is encapsulated in the microcapsule, so that it is advantageous from the viewpoint that the heat storage material which becomes a liquid at a high temperature can be prevented from leaking out of the heat storage sheet, the surrounding members and the like in which the heat storage sheet is used can be prevented from being contaminated, and the heat storage ability as the heat storage sheet can be maintained.

From the viewpoint of the heat storage property of the heat storage sheet, the content ratio of the heat storage material in the heat storage sheet to the total mass of the heat storage sheet is 65% by mass or more, is preferably 75% by mass or more, and more preferably 80% by mass or more. Further, from the viewpoint of the heat storage property of the heat storage sheet, the content ratio of the heat storage material in the heat storage sheet to the total mass of the heat storage sheet is preferably 99.9% by mass or less, more preferably 99% by mass or less, and further preferably 98% by mass or less.

The measurement of the content ratio of the heat storage material in the heat storage sheet is performed by the method as follows.

First, the heat storage material is extracted from the heat storage sheet, and the type of the heat storage material is identified. In a case in which the heat storage material is configured by a plurality of types, the mixing ratio thereof is also identified. Examples of the identification method include known methods such as nuclear magnetic resonance (NMR) measurement and infrared spectroscopy (IR) measurement. Further, as an example of the extracting method of the heat storage material from the heat storage sheet, there is a method of immersing the heat storage sheet in the solvent (for example, an organic solvent) to extract the heat storage material.

Next, the heat storage material included in the heat storage sheet identified by the above procedure is separately prepared, and a heat absorption amount (J/g) of the heat storage material alone is measured by using differential scanning calorimetry (DSC). The obtained heat absorption amount is defined as a heat absorption amount A. As described above, in a case in which the heat storage material is configured by a plurality of types, the heat storage material with the mixing ratio is separately prepared and the heat absorption amount is measured as described above.

Next, the heat absorption amount of the heat storage sheet is measured by the same method as above. The obtained heat absorption amount is defined as a heat absorption amount B.

Next, a ratio X (%) {(B/A)×100} of the heat absorption amount B to the heat absorption amount A is calculated. The ratio X corresponds to the content ratio of the heat storage material in the heat storage sheet (the ratio of the content of the heat storage material to the total mass of the heat storage sheet). For example, in a case in which the heat storage sheet is configured by only the heat storage material, the heat absorption amount A and the heat absorption amount B have the same value, and the ratio X (%) is 100%. On the other hand, in a case in which the content ratio of the heat storage material in the heat storage sheet is a predetermined ratio, the heat absorption amount is a value corresponding to the ratio. That is, by comparing the heat absorption amounts A and B, the content ratio of the heat storage material in the heat storage sheet can be obtained.

—Other Components—

Examples of other components which can be encapsulated in the microcapsule as the core material include the solvent and an additive such as the flame retardant.

Other components can be encapsulated in the microcapsule as the core material, but from the viewpoint of the heat storage property, the content ratio of the heat storage material in the core material to the total mass of the core material is preferably 80% by mass to 100% by mass, and more preferably 100% by mass.

(Solvent)

As the core material, the microcapsule may include the solvent as an oil component as long as the effects in the present disclosure are not significantly impaired.

As an example of the solvent, there is the heat storage material described above of which melting point is outside the temperature range in which the heat storage sheet is used (heat control range; for example, the operating temperature of the heat generating body). That is, the solvent refers to a solvent which does not change the phase or the like in the liquid state in the heat control range, and is distinguished from the heat storage material which causes a phase transition in the heat control range to cause an endothermic reaction or a heat dissipation reaction.

The content ratio of the solvent in the encapsulating component to the total mass of the encapsulating component is preferably less than 30% by mass, more preferably less than 10% by mass, and further preferably 1% by mass or less. The lower limit is not particularly limited, but 0% by mass can be adopted, for example.

The solvent may be used alone or may be used in the combination of two types or more.

(Additives)

In addition to the above components, the core material in the microcapsule can encapsulate, as needed, additives such as an ultraviolet absorbing agent, a light stabilizer, an antioxidant, a wax, and an odor suppressant.

˜Content Ratio of Microcapsule˜

In many cases, the content ratio of the microcapsule in the heat storage sheet to the total mass of the heat storage sheet is 70% by mass or more. Above all, it is preferably 75% by mass or more. By setting the content ratio of the microcapsule to 75% by mass or more, the presence amount of the heat storage materials to the total mass of the heat storage sheet can be increased, and as a result, the heat storage sheet which exhibits the excellent heat storage property is obtained.

It is preferable that the content ratio of the microcapsule in the heat storage sheet be high, from the viewpoint of the heat storage property. Specifically, the content ratio of the microcapsule in the heat storage sheet is preferably 80% by mass or more, more preferably 85% by mass to 99% by mass, and further preferably 90% by mass to 99% by mass.

The microcapsule may be used alone or may be used in the combination of two types or more.

[[Wall Portion (Capsule Warn]]

The microcapsule according to the present disclosure includes the wall portion (capsule wall) which encapsulates the core material.

The microcapsule has the capsule wall, so that capsule particles can be formed and the core material described above which forms the core portion can be encapsulated.

—Forming Material of Capsule Wall—

The material which forms the capsule wall in the microcapsule is not particularly limited as long as the material is a polymer, and examples thereof include polyurethane, polyurea, polyurethane urea, a melamine resin, an acrylic resin, and the like. From the viewpoint of thinning the capsule wall to impart the excellent heat storage property, polyurethane, polyurea, polyurethane urea, or a melamine resin is preferable, and polyurethane, polyurea, or polyurethane urea is more preferable. Also, polyurethane, polyurea, or polyurethane urea is more preferable from the viewpoint of preventing a case in which a phase change, a structural change, or the like of the heat storage material is unlikely to occur at the interface between the wall material and the heat storage material.

Further, it is preferable that the microcapsule be present as a deformable particle.

In a case in which the microcapsule is the deformable particle, the deformation can be made without breaking, and a filling rate of the microcapsule can be improved. As a result, it is possible to increase the amount of the heat storage material in the heat storage sheet, and it is possible to realize more excellent heat storage property. From such a viewpoint, polyurethane, polyurea, or polyurethane urea is preferable as the material which forms the capsule wall.

Deformation of microcapsule without breaking can be regarded as a deformed state as long as deformation is recognized from the shape of each microcapsule in a state in which no external pressure is applied, regardless of the degree of deformation. For example, it refers to a property of relieving the pressure applied to the capsule by deformation and maintaining the encapsulation state of the core material without breaking even in a case in which the microcapsules are pressed against each other in the sheet and the pressure applied to each capsule, in a case in which microcapsules are to be densely present in the sheet.

The deformation which occurs in the microcapsule includes, for example, deformation in which spherical surfaces come into contact with each other to form a flat contact surface in a case in which the microcapsules are pressed against each other in the sheet.

From the above viewpoint, the deformation rate of the microcapsule is preferably 10% or more, and more preferably 30% or more. Further, from the viewpoints of the physical strength and the durability of the capsule, the upper limit of the deformation rate of the microcapsule may be 80% or less.

˜Polyurethane, Polyurea, Polyurethane Urea˜

It is preferable that the capsule wall of the microcapsule according to the present disclosure include polyurethane, polyurea, or polyurethane urea.

It is preferable that polyurethane, polyurea, and polyurethane urea have structures derived from polyisocyanate, from the viewpoint of the storage stability. That is, it is preferable that polyurethane, polyurea, and polyurethane urea be polymers obtained by using polyisocyanate, from the viewpoint of the storage stability.

Polyurethane is a polymer which has a plurality of urethane bonds, and is preferably a reaction product of polyol and polyisocyanate.

Further, polyurea is a polymer which has a plurality of urea bonds, and is preferably a reaction product of polyamine and polyisocyanate.

Further, polyurethane urea is a polymer which has the urethane bond and the urea bond, and is preferably a reaction product of polyol, polyamine, and polyisocyanate. In a case in which polyol and polyisocyanate are reacted with each other, a part of polyisocyanate reacts with water to form polyamine, and as a result, polyurethane urea may be obtained.

Since polyurethane, polyurea, and polyurethane urea have a low glass transition temperature, the microcapsule which includes polyurethane, polyurea, or polyurethane urea as the capsule wall can be deformed without breaking. As a result, it is possible to improve the filling rate of the microcapsule. As a result, it is possible to increase the amount of the heat storage material in the heat storage sheet, and it is possible to realize more excellent heat storage property.

It is preferable that the material which forms polyurethane, polyurea, and polyurethane urea be selected from the group consisting of aromatic polyisocyanate and aliphatic polyisocyanate. Among these, it is preferable that the capsule wall to be formed include polyurethane, polyurea, or polyurethane urea which has a structural portion selected from the group consisting of a structural portion derived from aromatic polyisocyanate and a structural portion derived from aliphatic polyisocyanate. As a result, a stable microcapsule can be easily obtained even in a case in which the wall thickness is thinned.

The “structural portion” refers to a structure obtained by performing a urethane reaction or a urea reaction.

Further, as described above, as an example of the material which forms polyurethane, polyurea, and polyurethane urea, in addition to polyisocyanate (for example, aromatic polyisocyanate and aliphatic polyisocyanate), there is a compound (active hydrogen-containing compound) selected from the group consisting of polyol and polyamine.

Examples of the aromatic polyisocyanate include m-phenylene diisocyanate, p-phenylene diisocyanate, 2,6-tolylene diisocyanate, 2,4-tolylene diisocyanate, naphthalene-1,4-diisocyanate, diphenylmethane-4,4′-diisocyanate, 3,3′-dimethoxy-biphenyldiisocyanate, 3,3′-dimethyldiphenylmethane-4,4′-diisocyanate, xylylene-1,4-diisocyanate, xylylene-1,3-diisocyanate, 4-chloroxylylene-1,3-diisocyanate, 2-methylxylylene-1,3-diisocyanate, 4,4′-diphenylpropane diisocyanate, 4,4′-diphenylhexafluoropropane diisocyanate, and the like.

Examples of the aliphatic polyisocyanate include trimethylene diisocyanate, hexamethylene diisocyanate, propylene-1,2-diisocyanate, butylene-1,2-diisocyanate, cyclohexylene-1,2-diisocyanate, cyclohexylene-1,3-diisocyanate, cyclohexylene-1,4-diisocyanate, dicyclohexylmethane-4,4′-diisocyanate, 1,4-bis(isocyanatemethyl)cyclohexane, 1,3-bis(isocyanatemethyl)cyclohexane, isophorone diisocyanate, lysine diisocyanate, hydrogenated xylylene diisocyanate, and the like.

In the above, as an example of the bifunctional aliphatic polyisocyanate and aromatic polyisocyanate, there is the diisocyanate compound, but examples of the polyisocyanate also include a trifunctional triisocyanate compound inferred from the diisocyanate compound as aliphatic polyisocyanate and aromatic polyisocyanate, and a tetrafunctional tetraisocyanate compound.

Further, adducts of the above polyisocyanate and bifunctional alcohol or phenol such as an ethylene glycol compound or a bisphenol compound can also be used.

Examples of the condensates, the polymers, or the adducts using polyisocyanate include a burette or isocyanurate, which is a trimer of the above bifunctional isocyanate compound, a polyfunctional compound as adducts of polyol such as trimethylolpropane and the bifunctional isocyanate compound, formalin condensate of benzene isocyanate, the polymer of polyisocyanate which has the polymerizable group such as methacryloyloxyethyl isocyanate, lysine triisocyanate, and the like.

Polyisocyanate is described in the “Polyurethane resin handbook” (edited by Keiji Iwata, published by Nikkan Kogyo Shimbun, Ltd. (1987)).

Among the above, it is preferable that the capsule wall of the microcapsule include a polymer of trifunctional or more functional polyisocyanate.

Examples of the trifunctional or more functional polyisocyanate include trifunctional or more functional aromatic polyisocyanate, trifunctional or more functional aliphatic polyisocyanate, and the like. As an example of the trifunctional or more functional polyisocyanate, trifunctional or more functional polyisocyanate (adduct type) as an adduct (adduct) of bifunctional polyisocyanate (compound which has two isocyanate groups in the molecule) and a compound (for example, trifunctional or more functional polyol, polyamine, or polythiol) which has three or more active hydrogen groups in the molecule, or a trimer (biuret type or isocyanurate type) of bifunctional polyisocyanate is also preferable.

Specific examples of the trifunctional or more functional polyisocyanate include the adduct of 2,6-tolylene diisocyanate, 2,4-tolylene diisocyanate, or hexamethylene diisocyanate with trimethylolpropane, biuret, isocyanurate, and the like.

As the adduct type trifunctional or more functional polyisocyanate, a commercially available product on the market may be used. Examples of the commercially available product include Takenate (registered trademark) D-102, D-103, D-103H, D-103M2, P49-75S, D-110N, D-120N (isocyanate value=3.5 mmol/g), D-140N, D-160N (which are manufactured by Mitsui Chemicals, Inc.), Desmodur (registered trademark) L75, UL57SP (manufactured by Sumika Bayer Urethane Co., Ltd.), Coronate (registered trademark) HL, HX, L (manufactured by Nippon Polyurethane Industry Co., Ltd.), P301-75E (manufactured by Asahi Kasei Corporation), Burnock (registered trademark) D-750 (manufactured by DIC Corporation), and the like.

Among these, as the adduct type trifunctional or more functional polyisocyanate, at least one selected from Takenate (registered trademark) D-110N, D-120N, D-140N, D-160N manufactured by Mitsui Chemicals, Inc., and Burnock (registered trademark) D-750 manufactured by DIC Corporation is more preferable.

As the isocyanurate type trifunctional or more functional polyisocyanate, a commercially available product on the market may be used. Examples thereof include Takenate (registered trademark) D-127N, D-170N, D-170HN, D-172N, D-177N, D-204 (manufactured by Mitsui Chemicals, Inc.), Sumijour N3300 and Desmodur (registered trademark) N3600, N3900, Z4470BA (manufactured by Sumika Bayer Urethane Co., Ltd.), Coronate (registered trademark) HX, HX (manufactured by Nippon Polyurethane Industry Co., Ltd.), Duranate (registered trademark) TPA-100, TKA-100, TSA-100, TSS-100, TLA-100, TSE-100 (manufactured by Asahi Kasei Corporation), and the like.

As the biuret type trifunctional or more functional polyisocyanate, a commercially available product on the market may be used. Examples thereof include Takenate (registered trademark) D-165N, NP1100 (manufactured by Mitsui Chemicals, Inc.), Desmodur (registered trademark) N3200 (manufactured by Sumika Bayer Urethane Co., Ltd.), Duranate (registered trademark) 24A-100 (manufactured by Asahi Kasei Corporation), and the like.

Polyol is a compound which has two or more hydroxyl groups, and examples thereof include low molecular weight polyol (for example, aliphatic polyol or aromatic polyol), polyether-based polyol, polyester-based polyol, polylactone-based polyol, castor oil-based polyol, polyolefin-based polyol, and a hydroxyl group-containing amine-based compound.

The low molecular weight polyol means polyol which has a molecular weight of 300 or less, and examples thereof include bifunctional low molecular weight polyol such as ethylene glycol, diethylene glycol, and propylene glycol, and trifunctional or more functional low molecular weight polyol such as glycerin, trimethylolpropane, hexanetriol, pentaerythritol, sorbitol, and the like.

Examples of the hydroxyl group-containing amine-based compound include amino alcohol and the like, as an oxyalkylated derivative of the amino compound. Examples of the amino alcohol include propylene oxide or ethylene oxide adduct of the amino compound such as ethylenediamine such as N,N,N′,N′-tetrakis[2-hydroxypropyl]ethylenediamine, N,N,N′,N′-tetrakis[2-hydroxyethyl]ethylenediamine, and the like.

Polyamine is a compound which has two or more amino groups (primary amino group or secondary amino group), and examples thereof include aliphatic polyvalent amine such as diethylenetriamine, triethylenetetramine, 1,3-propylenediamine, and hexamethylenediamine; an epoxy compound adduct of aliphatic polyvalent amine; alicyclic polyvalent amine such as piperazine; heterocyclic diamine such as 3,9-bis-aminopropyl-2,4,8,10-tetraoxaspiro-(5,5)undecane, and the like.

[[Ratio of Capsule Wall and Heat Storage Material]] It is preferable that the mass of the capsule wall in the microcapsule to the mass of the heat storage material included in the core portion be 12% by mass or less. The fact that the mass of the capsule wall to the heat storage material which is the encapsulating component is 12% by mass or less indicates that the capsule wall is a thin wall. By thinning the capsule wall, the content of the microcapsule which encapsulates the heat storage material in the heat storage sheet is increased, and as a result, the heat storage property is more excellent.

It is more preferable that the mass of the capsule wall to the mass of the heat storage material be 10% by mass or less.

The lower limit of the mass of the capsule wall is not limited, but it is preferably 1% by mass or more, more preferably 2% by mass or more, and further preferably 3% by mass or more, based on the mass of the heat storage material included in the core portion, from the viewpoint of maintaining the pressure resistance of the microcapsule. The particularly preferable range of the mass of the capsule wall is 2% by mass to 12% by mass.

[[Physical Property of Microcapsule]]

A particle diameter of the microcapsule is preferably 1 μm to 80 μm, more preferably 10 μm to 70 μm, and further preferably 15 μm to 50 μm in terms of a volume-based median diameter (D50).

The volume-based median diameter of the microcapsule can be preferably controlled by changing the dispersion conditions and the like.

Where, the volume-based median diameter of the microcapsule is a diameter at which the total volume of particles on a large diameter side and a small diameter side is equal in a case in which the entire microcapsule is divided into two with the particle diameter at which a cumulative volume is 50% as a threshold value. The volume-based median diameter of the microcapsule is measured by using Microtrac MT3300EXII (manufactured by Nikkiso Co., Ltd.). In a separating method of the microcapsule, the heat storage sheet is cut into, for example, 2 cm×2 cm, immersed in the solvent such as water in which the microcapsule does not dissolve, for 24 hours or longer, and the obtained solvent dispersion liquid is centrifuged.

It is preferable that the particle diameter distribution of the microcapsule be present such that the microcapsules can be arranged most densely without any gaps.

In a case in which the microcapsule is not easily deformed, it is preferable that the small microcapsules be present to fill the gap formed between the large microcapsules. That is, depending on the particle diameter distribution, a polydisperse distribution may be better.

On the other hand, in a case in which the microcapsule is deformed to fill the gap, the larger microcapsule can encapsulate more heat storage materials using the thicker wall thickness. Therefore, it is preferable that the particle diameter distribution centered on the large microcapsule, that is, the distribution of the large microcapsule be sharp.

The particle diameter can be controlled, for example, by controlling the particle diameter distribution of the oil phase component when the microcapsule is formed, or by improving the stability of the oil phase. Further, in order to narrow the particle diameter distribution, it is conceivable to use an emulsification method such as a cylindrical mill, and it is possible to devise a design of a surfactant or the like to maintain a desired emulsified state or the particle diameter of the oil phase.

The thickness (wall thickness) of the capsule wall of the microcapsule is preferably 0.010 μm to 10 μm, and more preferably 0.050 μm to 10 μm. In a case in which the wall thickness of the microcapsule is 0.010 μm or more, leakage of the core material can be prevented. In a case in which the wall thickness of the microcapsule is 10 μm or less, there is an advantage that the microcapsules in the heat storage sheet, that is, the presence amount of the heat storage material can be increased.

From the same viewpoint as above, the wall thickness of the microcapsule is further preferably 0.050 μm to 5 μm, and particularly preferably 0.100 μm to 2 μm.

The wall thickness refers to an average value obtained by calculating and averaging the individual wall thicknesses (μm) of 20 microcapsules by using a scanning electron microscope (SEM). Specifically, the average value is obtained by the method in which a cross-sectional slice of the heat storage sheet is manufactured, the cross section is observed by using the SEM, 20 microcapsules are selected from the microcapsules which have a size of ±10% of the median diameter calculated by the measurement method described above, the cross sections of the individual 20 microcapsules are observed, the wall thicknesses are measured, and the average value is calculated.

It is preferable that the microcapsule described above satisfy the relationship of Expression (1). In a case in which the microcapsule satisfies Expression (1), the content ratio of the heat storage material in the heat storage sheet can be further increased.

δ/Dm≤0.010 Expression (1)

Where, δ represents a thickness (μm) of a capsule wall of the microcapsule. Dm represents a volume-based median diameter (μm) of the microcapsule.

The lower limit of δ/Dm is not particularly limited, but it is 0.001 or more in many cases.

[[Manufacturing Method of Microcapsule]]

The microcapsule according to the present disclosure can be manufactured, for example, by the following method.

In a case in which the capsule wall is formed of polyurethane, polyurea, or polyurethane urea, the microcapsule according to the present disclosure is manufactured by applying an interfacial polymerization method including a step (emulsification step) of dispersing the oil phase including the heat storage material and a capsule wall material in the water phase including the emulsifier to prepare an emulsified liquid, and a step (capsulizing step) of polymerizing the capsule wall material at the interface between the oil phase and the water phase to form the capsule wall, and forming the microcapsule which encapsulates the heat storage material.

Examples of the capsule wall material include the capsule wall material including polyisocyanate and at least one selected from the group consisting of polyol and polyamine. A part of polyisocyanate may react with water in a reaction system to be polyamine. Therefore, in a case in which the capsule wall material includes at least polyisocyanate, it is possible to convert a part of the polyisocyanate into polyamine and cause polyisocyanate to react with polyamine to synthesize polyurea.

In a case in which the capsule wall is formed of a melamine formaldehyde resin, a coacervation method including a step (emulsification step) of dispersing the oil phase including the heat storage material in the water phase including the emulsifier to prepare the emulsified liquid, and a step (capsulizing step) of adding the capsule wall material to the water phase, forming a polymer layer of the capsule wall material on a surface of emulsified liquid droplet, and forming the microcapsule which encapsulates the heat storage material can be appropriately used.

(Emulsification Step)

In the emulsification step, in a case in which the capsule wall is formed of polyurethane, polyurea, or polyurethane urea, the oil phase including the heat storage material and the capsule wall material is dispersed in the water phase including the emulsifier to prepare the emulsified liquid.

Further, in a case in which the capsule wall is formed of a melamine formaldehyde resin, the oil phase including the heat storage material is dispersed in the water phase including the emulsifier to prepare the emulsified liquid.

˜Emulsified Liquid˜

The emulsified liquid according to the present disclosure is formed by dispersing the oil phase including the heat storage material and, as needed, the capsule wall material in the water phase including the emulsifier.

(1) Oil Phase

The oil phase includes at least the heat storage material, and as needed, may further include components such as the capsule wall material, the solvent, and/or the additive.

Examples of the solvent include the heat storage material described above of which melting point is outside the temperature range in which the heat storage sheet is used (heat control range; for example, the operating temperature of the heat generating body).

(2) Water Phase

The water phase according to the present disclosure can include at least an aqueous medium and the emulsifier.

—Aqueous Medium—

As an example of the aqueous medium, there are water, and a mixed solvent of water and a water-soluble organic solvent, and water is preferable. The “water-soluble” of the water-soluble organic solvent means that a dissolved amount of a target substance in 100% by mass of water at 25° C. is 5% by mass or more.

The aqueous medium is preferably 20% by mass to 80% by mass, more preferably 30% by mass to 70% by mass, and further preferably 40% by mass to 60% by mass, based on the total mass of the emulsified liquid which is a mixture of the oil phase and the water phase.

—Emulsifier—

The emulsifier includes a dispersing agent, a surfactant, or a combination thereof.

Examples of the dispersing agent include a binder which will be described below, and polyvinyl alcohol is preferable.

As the polyvinyl alcohol, a commercially available product on the market may be used, and examples thereof include Kuraray Poval series manufactured by Kuraray Co., Ltd. (for example, Kuraray Poval PVA-217E, Kuraray Poval KL-318, or the like).

From the viewpoint of the dispersibility of the microcapsule, the degree of polymerization of polyvinyl alcohol is preferably 500 to 5000, and more preferably 1000 to 3000.

Examples of the surfactant include a nonionic surfactant, an anionic surfactant, a cationic surfactant, an amphoteric surfactant, and the like. The surfactant may be used alone or may be used in the combination of two types or more.

It is preferable that the emulsifier be able to be bonded to polyisocyanate described above in terms of improving a film hardness. For example, in the case in which microcapsule is manufactured by using the capsule wall material including polyisocyanate, polyvinyl alcohol as the emulsifier is able to be bonded to polyisocyanate. That is, the hydroxyl group in polyvinyl alcohol is able to be bonded to polyisocyanate.

The concentration of the emulsifier is preferably more than 0% by mass and 20% by mass or less, more preferably 0.005% by mass to 10% by mass, further preferably 0.01% by mass to 10% by mass, and particularly preferably 1% by mass to 5% by mass, based on the total mass of the emulsified liquid which is a mixture of the oil phase and the water phase.

As will be described below, in a case in which the heat storage sheet is manufactured by using the dispersion liquid in which the microcapsules produced by using the emulsifier are dispersed, the emulsifier may remain as the binder in the heat storage sheet. As will be described below, in order to reduce the content ratio of the binder in the heat storage sheet, it is preferable that the usage amount of the emulsifier be small as long as the emulsification performance is not impaired.

The water phase may include other components such as an ultraviolet absorbing agent, an antioxidant, and a preservative, as needed.

˜Dispersion˜

Dispersion refers to dispersing the oil phase as oil droplets in the water phase (emulsification). Dispersion can be performed by using a unit usually used to disperse the oil phase and the water phase, such as homogenizer, manton gaulin, ultrasound disperser, dissolver, keddy mill, or other known dispersion apparatuses.

The mixing ratio of the oil phase to the water phase (oil phase mass/water phase mass) is preferably 0.1 to 1.5, more preferably 0.2 to 1.2, and further preferably 0.4 to 1.0. In a case in which the mixing ratio is in the range of 0.1 to 1.5, the viscosity can be maintained at an appropriate level, the manufacturing suitability is excellent, and the stability of the emulsified liquid is excellent.

(Capsulizing Step)

In the capsulizing step, the capsule wall material is polymerized at the interface between the oil phase and the water phase to form the capsule wall, and a microcapsule which encapsulates the solvent is formed.

˜Polymerization˜

Polymerization is a step of polymerizing the capsule wall material included in the oil phase in the emulsified liquid at the interface with the water phase to form the capsule wall. The polymerization is preferably performed under heating. A reaction temperature in the polymerization is usually preferably 40° C. to 100° C., and more preferably 50° C. to 80° C. A reaction time of polymerization is usually preferably about 0.5 hour to 10 hours, and more preferably about 1 hour to 5 hours. The polymerization time is shorter as the polymerization temperature is higher, but in a case in which encapsulating material or capsule wall material which may decompose at a high temperature is used, it is desirable to select a polymerization initiator which acts at a low temperature to polymerize at a relatively low temperature.

In order to prevent the aggregation of the microcapsules in a polymerization step, it is preferable that an aqueous solution (for example, water, an aqueous acetic acid solution, or the like) be further added to reduce the collision probability between the microcapsules, and it is also preferable that sufficient stirring be performed. A dispersing agent for preventing aggregation may be added again in the polymerization step. Further, as needed, a charge adjusting agent such as nigrosin or any other auxiliary agent can be added. These auxiliary agents can be added when forming the capsule wall or in any point in time.

In the present disclosure, in a case in which the heat storage sheet is manufactured as will be described below, a microcapsule-containing composition obtained by mixing microcapsules and a dispersion medium may be used. By including the dispersion medium, the microcapsule-containing composition can be easily mixed in a case of used for various applications.

The dispersion medium can be appropriately selected depending on the intended use of the microcapsule. The dispersion medium is preferably a liquid component which does not affect the wall material of the microcapsule, and examples thereof include an aqueous solvent, a viscosity adjuster, a stabilizer, and the like. Examples of the stabilizer include the emulsifier which can be used in the water phase described above.

Examples of the aqueous solvent include water and alcohol, and ion exchange water and the like can be used.

The content ratio of the dispersion medium in the microcapsule-containing composition need only be appropriately selected depending on the intended use.

[Binder]

It is preferable that the heat storage sheet according to the present disclosure contain, in addition to the microcapsule, at least one binder outside the microcapsule. Since the heat storage sheet contains the binder, durability can be imparted.

As described above, the emulsifier such as polyvinyl alcohol may be used in a case in which the microcapsule is manufactured. Therefore, in a case in which the heat storage sheet is manufactured by using the microcapsule-containing composition formed by using the emulsifier, the heat storage sheet may include the binder derived from the emulsifier.

The binder is not particularly limited as long as it is a polymer which can form a film, and examples thereof include a water-soluble polymer, an oil-soluble polymer, and the like.

The “water-soluble” in the water-soluble polymer means that the dissolved amount of the target substance in 100% by mass of water at 25° C. is 5% by mass or more, and a more suitable water-soluble polymer has a dissolved amount of 10% by mass or more.

Further, the “oil-soluble polymer” which will be described below means a polymer other than the “water-soluble polymer” described above.

Examples of the water-soluble polymer include polyvinyl alcohol and its modified product, polyacrylic acid amide and its derivative, a styrene-acrylic acid copolymer, sodium polystyrene sulfonate, an ethylene-vinyl acetate copolymer, a styrene-maleic acid anhydride copolymer, an ethylene-maleic acid anhydride copolymer, an isobutylene-maleic acid anhydride copolymer, a polyvinylpyrrolidone, ethylene-acrylic acid copolymer, a vinyl acetate-acrylic acid copolymer, carboxymethyl cellulose, methyl cellulose, casein, gelatin, a starch derivative, gum arabic, sodium alginate, and the like, and polyvinyl alcohol is preferable.

Examples of the oil-soluble polymer include polymers having the heat storage property disclosed in WO2018/207387A and JP2007-031610A. Specifically, a polymer which has a long-chain alkyl group which has 12 to 30 carbon atoms is preferable, and an acrylic resin which has a long-chain alkyl group which has 12 to 30 carbon atoms is more preferable.

In addition to the above, examples of the oil-soluble polymer include modified products of polyvinyl alcohol, a derivative of polyacrylic acid amide, ethylene-vinyl acetate copolymer, styrene-maleic acid anhydride copolymer, ethylene-maleic acid anhydride copolymer, isobutylene-maleic acid anhydride copolymer, ethylene-acrylic acid copolymer, vinyl acetate-acrylic acid copolymer, styrene-acrylic acid copolymer, and the like.

Among the above, as the preferable binder, from the viewpoint of making the content ratio of microcapsule in the heat storage sheet 70% by mass or more (preferably, 75% by mass or more), the water-soluble polymer is preferable, polyol is more preferable, and polyvinyl alcohol is further preferable. To use the water-soluble polymer is suitable for forming the sheet while maintaining the dispersibility in a case in which an oil in a water type (0/W type) microcapsule liquid using the oil-soluble material such as paraffin as the core material is prepared. Therefore, it is easy to adjust the content ratio of the microcapsule in the heat storage sheet to 70% by mass or more.

As the polyvinyl alcohol, a commercially available product on the market may be used, and as an example, there is Kuraray Poval series manufactured by Kuraray Co., Ltd. (for example, Kuraray Poval PVA-217E, Kuraray Poval KL-318, or the like).

In a case in which the binder is polyvinyl alcohol, from the viewpoints of the dispersibility and the film hardness of the microcapsule, the degree of polymerization of polyvinyl alcohol is preferably 500 to 5000, and more preferably 1000 to 3000.

From the viewpoint of easily adjusting the content ratio of the microcapsule in the heat storage sheet to 70% by mass or more while maintaining the film hardness of the heat storage sheet, the content ratio of the binder in the heat storage sheet is preferably 0.1% by mass to 20% by mass, and more preferably 1% by mass to 11% by mass.

The smaller content ratio of the binder is preferable in that the amount of microcapsule to the total mass can be increased. Further, in a case in which the content ratio of the binder is in a range not too low, it is easy to protect the microcapsule and maintain the ability of forming the layer which includes the microcapsules, so that microcapsule which has the physical strength can be easily obtained.

In the heat storage sheet, the content ratio of the binder to the total mass of the microcapsule is not particularly limited, but it is preferably 15% by mass or less, and more preferably 11% by mass or less, from the viewpoint of more excellent heat storage property of the heat storage sheet. The lower limit is not particularly limited, but it is preferably 0.1% by mass or more.

˜Molecular Weight˜

From the viewpoint of the film hardness, a number average molecular weight (Mn) of the binder is preferably 20,000 to 300,000, and more preferably 20,000 to 150,000.

For the measurement of molecular weight, a value is measured by gel permeation chromatography (GPC).

For the measurement by gel permeation chromatography (GPC), HLC (registered trademark)-8020 GPC (manufactured by Tosoh Corporation) is used as a measuring device, and three TSK gel (registered trademark) Super Multipore HZ-H (4.6 mm ID x 15 cm, manufactured by Tosoh Corporation) are used as a column, and THF (tetrahydrofuran) is used as the eluent. As a measurement condition, a sample concentration is 0.45% by mass, a flow rate is 0.35 ml/min, a sample injection amount is 10 μl, a measurement temperature is 40° C., and a refractive index (RI) detector is used.

The calibration curve is produced from 8 samples of “standard sample TSK standard polystyrene” manufactured by Tosoh Corporation: “F-40”, “F-20”, “F-4”, “F-1”, “A-5000”, “A-2500”, “A-1000”, and “n-propylbenzene”.

[Other Components]

The heat storage sheet according to the present disclosure may include other components such as a thermal conductive material, a flame retardant, an ultraviolet absorbing agent, an antioxidant, and a preservative in the outside of the microcapsule, as needed.

The content ratio of the other components which may be outside the microcapsule to the total mass of the heat storage sheet is preferably 10% by mass or less, and more preferably 5% by mass or less. Further, the total amount of the microcapsule and the binder to the total mass of the heat storage sheet is preferably 80% by mass or more, more preferably 90% by mass to 100% by mass, and further preferably 98% by mass to 100% by mass.

—Thermal Conductive Material—

It is preferable that the heat storage sheet according to the present disclosure further include the thermal conductive material in the outside the microcapsule. By including the thermal conductive material, the heat radiation property from the heat storage sheet after heat storage is excellent, and it is easy to satisfactorily perform the cooling efficiency, the cooling rate, the temperature maintaining, and the like of the heat generating body which generates heat.

The “thermal conductivity” of the thermal conductive material means a material having the thermal conductivity of 10 Wm⁻¹K⁻¹ or more. Above all, it is preferable that the thermal conductivity of the thermal conductive material be 50 Wm⁻¹K⁻¹ or more, from the viewpoint of improving the heat radiation property of the heat storage sheet.

The thermal conductivity (unit: Wm⁻¹K⁻¹) is a value measured by a flash method at a temperature of 25° C. by a method compliant with Japanese Industrial Standards (JIS) R1611.

Examples of the thermal conductive material include carbon (artificial graphite, carbon black, or the like; 100 to 250), carbon nanotubes (3000 to 5500), metals (for example, silver: 420, copper: 398, gold: 320, aluminum: 236, iron: 84, platinum: 70, stainless steel: 16.7 to 20.9, nickel: 90.9), silicone (Si; 168), and the like.

The numerical values in parentheses described above indicate the thermal conductivity (unit: Wm⁻¹K⁻¹) of each material.

It is preferable that the content ratio of the thermal conductive material in the heat storage sheet to the total mass of the heat storage sheet be 2% by mass or more. From the viewpoint of the balance between heat storage and heat radiation of the heat storage sheet, the content ratio of the thermal conductive material is preferably 10% by mass or less, and more preferably 5% by mass or less.

—Flame Retardant—

It is preferable that the heat storage sheet according to the present disclosure further include the flame retardant. The flame retardant may be included in the inside, the wall portion, or the outside of the microcapsule, but it is preferable that the flame retardant be included outside the microcapsule, from the viewpoint of not changing the characteristics such as heat storage property of the microcapsule and the strength of the microcapsule wall portion.

The flame retardant is not particularly limited, and known materials can be used. For example, the flame retardant described in “Practical application and technology of flame retardant materials” (published by CMC Publishing Co., Ltd.) can be used, and generally, a halogen-based flame retardant, a phosphorus-based flame retardant, and an inorganic flame retardant are preferably used. In a case in which it is desirable to suppress the mixing of halogen in electronic applications, the phosphorus-based flame retardant and the inorganic flame retardant are preferably used.

Examples of the phosphorus-based flame retardant include phosphate materials such as triphenyl phosphate, tricresyl phosphate, trixylenyl phosphate, cresyl phenyl phosphate, and 2-ethylhexyl diphenyl phosphate, other aromatic phosphate esters, aromatic condensed phosphate esters, polyphosphates, phosphinic acid metal salts, red phosphorus, and the like.

The content ratio of the flame retardant in the heat storage sheet to the total mass of the heat storage sheet is preferably 0.1% by mass to 20% by mass, more preferably 1% by mass to 15% by mass, and further preferably 1% by mass to 5% by mass, from the viewpoints of the heat storage property and the flame retardance.

It is also preferable to include an auxiliary flame retardant in combination with the flame retardant. Examples of the auxiliary flame retardant include pentaerythritol, phosphorous acid, 22-oxidized tetrazinc 12-boron heptahydrate, and the like.

[Physical Property of Heat Storage Sheet]

(Thickness)

A thickness of the heat storage sheet is preferably 1 μm to 1000 μm, and more preferably 1 μm to 500 μm.

The thickness is an average value obtained by observing the cut cross section of the heat storage sheet cut in parallel to the thickness direction with SEM, measuring any 5 points, and averaging the thicknesses of the 5 points.

(Latent Heat Capacity)

From the viewpoints of the high heat storage property and the suitability for temperature control of a heat generating body which generates heat, the latent heat capacity of the heat storage sheet according to the present disclosure is preferably 110 J/ml or more, more preferably 135 J/ml or more, and further preferably 145 J/ml or more. The upper limit is not particularly limited, but it is 400 J/ml or less in many cases.

The latent heat capacity is a value calculated from a result of the differential scanning calorimetry (DSC) and the thickness of the heat storage sheet.

From the viewpoint of exhibiting a high amount of heat storage in a limited space, it is considered appropriate to grasp the amount of heat storage in terms of “J/ml (amount of heat storage per unit volume)”, but in a case in which the applications to the electronic device are considered, the weight of the electronic device is also important. Therefore, in a case in which it is considered that a high heat storage property is exhibited in a limited mass, it may be appropriate to grasp the heat storage property in terms of “J/g (amount of heat storage per unit mass)”. In this case, the latent heat capacity is preferably 140 J/g or more, more preferably 150 J/g or more, further preferably 160 J/g or more, and particularly preferably 190 J/g or more. The upper limit is not particularly limited, but it is 450 J/g or less in many cases.

(Void Volume)

In a case in which there is a void in the heat storage sheet, the volume corresponding to the void is large as compared with a case in which the amount of microcapsules is the same. Therefore, in a case in which the space occupied by the heat storage sheet is to be reduced, it is preferable that the heat storage sheet do not have the void. A ratio of the volume of the microcapsule to the volume of the heat storage sheet is preferably 40% by volume or more, more preferably 60% by volume or more, and further preferably 80% by volume or more. The upper limit is not particularly limited, but 100% by volume can be adopted, for example.

From such a viewpoint, the ratio (void volume) of the volume of the void in the heat storage sheet is preferably 50% by volume or less, more preferably 40% by volume or less, further preferably 20% by volume or less, particularly preferably 15% by volume or less, and most preferably 10% by volume or less. The lower limit is not particularly limited, but 0% by volume can be adopted, for example.

[Manufacturing Method of Heat Storage Sheet]

The manufacturing method of the heat storage sheet is not particularly limited, and for example, the heat storage sheet can be manufactured by applying the dispersion liquid including the microcapsule which encapsulates the heat storage material and the binder, which is used as needed, onto the base material and drying the liquid. Then, by peeling off a coating film after drying from the base material, a simple substance of the heat storage sheet can be obtained.

Examples of the coating method include a die coating method, an air knife coating method, a roll coating method, a blade coating method, a gravure coating method, a curtain coating method, and the like, and the blade coating method, the gravure coating method, or the curtain coating method is preferable. Further, a method of forming a layer by casting the dispersion liquid including microcapsule which encapsulates the heat storage material and the binder can also be performed.

In the case of a water medium, it is preferable that the drying be performed in the range of 60° C. to 130° C.

In a step of drying, the layer which includes the microcapsules (for example, the heat storage sheet formed of a single layer) may be flattened by using a roller. Alternatively, the operation of applying pressure to the layer which includes microcapsules (for example, the heat storage sheet formed of a single layer) by using a nip roller, a calender, or the like to increase the filling rate of a microcapsule in the film may be performed.

Further, in order to reduce the void volume in the heat storage sheet, it is preferable to adopt the method, such as using the microcapsule which is easily deformed, performing drying gently in a case in which the layer which includes the microcapsules is formed, or performing coating in a plurality of times without forming a thick coating layer at one time.

One of the suitable embodiments of the manufacturing method of a heat storage sheet is a method including a step A of mixing a heat storage material, polyisocyanate, at least one active hydrogen-containing compound selected from the group consisting of polyol and polyamine, and an emulsifier to produce a dispersion liquid including a microcapsule which encapsulates at least a part of the heat storage material, and a step B of manufacturing a heat storage sheet by using the dispersion liquid without substantially adding a binder to the dispersion liquid.

According to the method, since the heat storage sheet is manufactured without using the binder, the content ratio of the microcapsule in the heat storage sheet can be increased, and as a result, the content ratio of the heat storage material in the heat storage sheet can be increased.

That is, the content ratio (encapsulation ratio) of the heat storage material which is encapsulated in the microcapsule is preferably 95% by mass or more based on the total mass of the heat storage material used in the step A. The upper limit is not particularly limited, but 100% by mass can be adopted, for example.

The description of the material used in the step A (heat storage material, polyisocyanate, at least one active hydrogen-containing compound selected from the group consisting of polyol and polyamine, and the emulsifier) is as above.

Further, as for the procedure for manufacturing the microcapsule in the step A, the method described above can be adopted, for example. More specifically, as the specific procedure of the step A, it is preferable to perform the step (emulsification step) of dispersing the oil phase including the heat storage material and the capsule wall material (polyisocyanate and active hydrogen-containing compound) in the water phase including the emulsifier to prepare the emulsified liquid, and the step (capsulizing step) of polymerizing the capsule wall material at the interface between the oil phase and the water phase to form the capsule wall, and forming the dispersion liquid including the microcapsule which encapsulates the heat storage material.

In the procedure of the step B, no binder is substantially added to the dispersion liquid including the microcapsule produced above. That is, the dispersion liquid obtained in the step A is used in manufacturing of the heat storage sheet without substantially adding the binder. Where, “without substantially adding the binder” means that the added amount of the binder to the total mass of the microcapsule in the dispersion liquid is 1% by mass or less, and preferably 0.1% by mass or less. Above all, it is preferable that the added amount of the binder be 0% by mass.

In the step B, as a procedure for manufacturing the heat storage sheet by using the dispersion liquid, as described above, it can be manufactured by applying and drying the liquid on the base material.

The suitable embodiment of the manufacturing procedure and manufacturing conditions of the step B are as described in the [Manufacturing Method of Heat Storage Sheet] described above.

<Heat Storage Member>

The heat storage member according to the present disclosure includes the heat storage sheet described above according to the present disclosure, and the base material. Since the heat storage sheet according to the present disclosure is provided, the heat storage member according to the present disclosure is excellent in heat storage property.

The heat storage member may be a roll type. Further, it may be produced by cutting out or punching out the heat storage member in the roll type or a sheet type into a desired size and shape.

[Heat Storage Sheet]

Details of the heat storage sheet according to the present disclosure are as described above, and the description thereof is omitted here.

From the viewpoint of the amount of heat storage, the thickness of the heat storage sheet in the heat storage member to the entire thickness of the heat storage member is preferably 50% or more, more preferably 70% or more, further preferably 80% or more, and particularly preferably 90% or more. Further, from the viewpoint of the amount of heat storage, the upper limit of the thickness of the heat storage sheet in the heat storage member is preferably 99.9% or less, and more preferably 99% or less.

[Base Material]

As the base material, for example, a resin base material such as polyester (for example, polyethylene terephthalate and polyethylene naphthalate), polyolefin (for example, polyethylene and polypropylene), and polyurethane, a glass base material, a metal base material, and the like can be appropriately selected. It is also preferable to add a function of improving the thermal conductivity in a plane direction or a film thickness direction and quickly diffusing heat from a heat generating portion to a heat storage portion to the base material. In that case, it is preferable that a metal base material and a thermal conductive material such as a graphite sheet or a graphene sheet be used as the base material.

The thickness of the base material is not particularly limited, and need only be appropriately selected depending on the purpose and the case. It is preferable the thickness of the base material be thick to some extent from the viewpoint of the handleability, and it is preferable that the thickness be thin, from the viewpoint of the amount of heat storage (content ratio of the microcapsule in the heat storage sheet).

The thickness of the base material is preferably 1 μm to 100 μm, more preferably 1 μm to 25 μm, and further preferably 3 μm to 15 μm.

It is preferable that a surface of the base material according to the present disclosure be subjected to surface treatment of the base material for a purpose of improving the adhesiveness to the heat storage sheet. Examples of a surface treatment method include corona treatment, plasma treatment, providing of an easily adhesive layer, and the like.

It is preferable that the base material according to the present disclosure include the easily adhesive layer, from the viewpoint of improving the adhesiveness between the base material and the heat storage sheet. It is preferable that the easily adhesive layer be formed of a resin layer which has a polymer. The heat storage member in which the easily adhesive layer is provided between the heat storage sheet and the base material according to the present disclosure improves the adhesiveness between the base material and the heat storage sheet, and also improves the adhesiveness between the base material and an adherend in a case of being adhering to the adherend such as the heat generating body which will be described below. It is presumed that improvement is due to the following reasons.

In the heat storage sheet according to the present disclosure, the content ratio of the heat storage material is 65% by mass or more, and thus the ratio of the binder included in the heat storage sheet is small in contrast. Therefore, in a case in which the heat storage member and the adherend adhere to each other, it is considered that the binder of the heat storage sheet does not easily absorb the external stress and the external stress concentrates on the interface between the heat storage sheet and the base material. On the other hand, in a case in which the easily adhesive layer is provided between the heat storage sheet and the base material, it is presumed that the easily adhesive layer can absorb the external stress, and thus the adhesion between the heat storage member and the adherend is improved.

It is preferable that the easily adhesive layer have a hydrophilicity-hydrophobicity and affinity with both the materials of the heat storage sheet and the base material and adhere well, and the preferable material differs depending on the material of the heat storage sheet. It is preferable that the polymer of the easily adhesive layer be a polymer different from the polymer of the base material, from the viewpoint of improving the adhesion between the base material and the heat storage sheet.

The polymer which configures the easily adhesive layer is not particularly limited, but styrene-butadiene rubber, an urethane resin, an acrylic resin, a silicone resin, or a polyvinyl resin is preferable. In a case in which the base material includes polyethylene terephthalate (PET), and the heat storage sheet includes at least one selected from the group consisting of polyurethane urea, polyurethane, and polyurea, or includes polyvinyl alcohol, as the material configuring the easily adhesive layer, for example, styrene-butadiene rubber or an urethane resin is preferably used.

From the viewpoint of the film hardness and adhesiveness, it is preferable to introduce a cross-linking agent into the easily adhesive layer. It is considered that an appropriate amount of the cross-linking agent is present to prevent the film itself from aggregation failure and being easily peeled off, and to prevent the film from being too hard from the viewpoint of the adhesiveness.

In the easily adhesive layer, a configuration can be adopted in which a material which easily adheres to the base material is on the base material side, a material which easily adheres to the heat storage sheet is on the heat storage sheet side, and two or more materials are mixed or two or more layers are stacked.

It is preferable that the thickness of the easily adhesive layer be thick, from the viewpoint of further improving the adhesiveness between the base material and the heat storage sheet and the adhesion between the heat storage member and the adherend, but in a case in which the thickness is too thick, the amount of heat storage of entire heat storage member is reduced. Therefore, the thickness of the easily adhesive layer is preferably 0.1 μm to 5 μm, and more preferably 0.5 μm to 2 μm.

[Adhesion Layer]

The adhesion layer can be provided on a side of the base material opposite to a side provided with the heat storage sheet. The adhesion layer can be provided to closely attaching the heat storage sheet to the adherend such as the heat generating body which will be described below.

The adhesion layer is not particularly limited and can be appropriately selected depending on the intended purpose, for example, there is a layer which includes a known pressure sensitive adhesive (also referred to as a pressure sensitive adhesive layer) or a layer which includes an adhesive (also referred to as an adhesive layer).

Examples of the pressure sensitive adhesive include an acrylic pressure sensitive adhesive, a rubber-based pressure sensitive adhesive, a silicone-based pressure sensitive adhesive, and the like. Further, examples of the pressure sensitive adhesive include the acrylic pressure sensitive adhesive, the ultraviolet (UV) hardening pressure sensitive adhesive, the silicone pressure sensitive adhesive, and the like described in “Characteristic evaluation of peeling paper/peeling film and pressure sensitive adhesive tape and its control technology”, published by Johokiko Co., Ltd., 2004, Chapter 2.

The acrylic pressure sensitive adhesive refers to a pressure sensitive adhesive including a polymer ((meth)acrylic polymer) of a (meth)acrylic monomer.

Further, the pressure sensitive adhesive layer may include a viscosity imparting agent.

Examples of the adhesive include a urethane resin adhesive, a polyester adhesive, an acrylic resin adhesive, an ethylene vinyl acetate resin adhesive, a polyvinyl alcohol adhesive, a polyamide adhesive, a silicone adhesive, and the like. The urethane resin adhesive or the silicone adhesive is preferable from the viewpoint of the higher adhesive strength.

˜Forming Method of Adhesion Layer˜

The forming method of the adhesion layer is not particularly limited, and examples thereof include a forming method of transferring the adhesion layer onto the base material, a forming method of applying a composition including the pressure sensitive adhesive or the adhesive onto the base material, and the like.

From the viewpoint of the pressure sensitive adhesive strength, handleability, and the amount of heat storage, the thickness of the adhesion layer is preferably 0.5 μm to 100 μm, more preferably 1 μm to 25 μm, and further preferably 1 μm to 15 μm.

A peeling sheet may adhere to a side of the adhesion layer opposite to a side facing the base material. Since the peeling sheet adheres, for example, in a case in which the microcapsule dispersion liquid is applied onto the base material, the handleability in a case of the thin thicknesses of the base material and the adhesion layer can be improved.

The peeling sheet is not particularly limited, and for example, a peeling sheet in which a peeling material such as silicone is attached on a support such as PET or polypropylene can be suitably used.

(Protective Layer)

In the heat storage member according to the present disclosure, a protective layer can be provided on a side of the heat storage sheet opposite to a side provided with the base material.

By providing the protective layer, it is possible to prevent scratches and folding in the process of manufacturing the heat storage member, and to provide handleability, and flame retardance, and the like.

The protective layer is not particularly limited, and can be appropriately selected depending on the intended purpose. Examples thereof include a layer which includes a known hard coating agent or a hard coating film as disclosed in JP2018-202696A, JP2018-183877A, and JP2018-111793A.

From the viewpoint of the heat storage property, it is also preferable that the protective layer include a polymer having a heat storage property as disclosed in WO2018/207387A and JP2007-031610A.

From the viewpoint of the amount of heat storage, it is preferable that the thickness of the protective layer be thin, and the thickness is preferably 50 μm or less, more preferably 0.01 μm to 25 μm, and further preferably 0.5 μm to 15 μm.

The protective layer can be formed by a known method.

The protective layer may be formed, for example, by allowing a protective base material formed of the same material as the base material to adhere to the heat storage sheet via the pressure sensitive adhesive, or may be formed by applying a protective layer forming composition which includes the binder onto the heat storage sheet to form the coating film. In the latter case, it is preferable that a solvent be included in the protective layer forming composition which includes the binder, in addition to the material which forms the film. In that case, it is preferable that the solvent be volatilized after coating by providing the drying step. Further, from the viewpoint of improving the coatability and the flame retardance, the protective layer forming composition which includes the binder may include additives such as the surfactant and the flame retardant. Further, it is preferable that the protective layer have the flexibility which is hard to be cracked and broken and a hard coat property which is hard to be scratched. From such a viewpoint, it is preferable that the protective layer forming composition include a reactive monomer, oligomer, and polymer which is hardened by heat or radiation (for example, an acrylic resin, an urethane resin, or rubber), a cross-linking agent, a thermal initiator, a photoinitiator, or the like.

The protective layer may be formed by simultaneous multi-layer coating in a case in which the layer which includes the microcapsule is formed.

(Flame Retardant Layer)

It is preferable that the heat storage sheet according to the present disclosure include a flame retardant layer. The position of the flame retardant layer is not particularly limited, and it may be integrated with the protective layer or provided as a separate layer. In a case in which it is provided as a separate layer, it is preferable that the flame retardant layer be stacked between the protective layer and the heat storage sheet.

A case in which it is integrated with the protective layer means that the protective layer has a flame retardant function. In particular, in a case in which the heat storage material is a flammable material such as paraffin, the entire heat storage member can be made to have flame retardance by including a flame retardant protective layer or a flame retardant layer.

The flame retardant protective layer and the flame retardant layer are not particularly limited as long as the layers have the flame retardance, but it is preferable that the layers be formed of a flame retardant organic resin such as a polyetheretherketone resin, a polycarbonate resin, a silicone resin, and a fluorine-containing resin, and an inorganic material such as a glass film. Where, it is possible to form the glass film by, for example, applying a silane coupling agent or a siloxane oligomer onto the heat storage sheet, and heating and drying the agent.

As a forming method of the flame retardant protective layer, a flame retardant may be mixed in the resin of the protective layer to form the flame retardant protective layer. As an example of the flame retardant, the flame retardant included in the heat storage sheet as described above and inorganic particles such as silica are preferably adopted. The amount and type of inorganic particles can be adjusted, including the type of the resin, depending on the surface shape and film quality. The size of the inorganic particle is preferably 0.01 μm to 1 μm, more preferably 0.05 μm to 0.2 μm, and further preferably 0.1 μm to 0.1 μm. The content ratio of the inorganic particles to the total mass of the protective layer is preferably 0.1% by mass to 50% by mass, and more preferably 1% by mass to 40% by mass.

The content ratio of the flame retardant in the protective layer to the total mass of the protective layer is preferably 0.1% by mass to 20% by mass, more preferably 1% by mass to 15% by mass, and further preferably 1% by mass to 5% by mass, from the viewpoints of the amount of heat storage and the flame retardance.

Further, from the viewpoints of the amount of heat storage and the flame retardance, the thickness of the flame retardant protective layer is preferably 0.1 μm to 20 μm, more preferably 0.5 μm to 15 μm, and further preferably 0.5 μm to 10 μm.

(Latent Heat Capacity)

From the viewpoints of the high heat storage property and suitability for temperature control of a heat generating body which generates heat, the latent heat capacity of the heat storage member according to the present disclosure is preferably 105 J/ml or more, more preferably 120 J/ml or more, and further preferably 130 J/ml or more. The upper limit is not particularly limited, but is 400 J/ml or less in many cases.

The latent heat capacity is a value calculated from a result of the differential scanning calorimetry (DSC) and the thickness of the heat storage member.

From the viewpoint of exhibiting a high amount of heat storage in a limited space, it is considered appropriate to grasp the amount of heat storage in terms of “J/ml (amount of heat storage per unit volume)”, but in a case in which the applications to the electronic device are considered, the weight of the electronic device is also important. Therefore, in a case in which it is considered that a high heat storage property is exhibited in a limited mass, it may be appropriate to grasp the heat storage property in terms of “J/g (amount of heat storage per unit weight)”. In this case, the latent heat capacity of the heat storage member is preferably 120 J/g or more, more preferably 140 J/g or more, further preferably 150 J/g or more, and particularly preferably 160 J/g or more. The upper limit is not particularly limited, but it is 450 J/g or less in many cases.

<Electronic Device>

The electronic device according to the present disclosure includes the heat storage sheet or the heat storage member.

The electronic device may include members other than the heat storage sheet and the heat storage member. Examples of other members include the heat generating body, the thermal conduction material, the adhesive, the base material, and the like. It is preferable that the electronic device include at least one of the heat generating body or the thermal conduction material.

One of the suitable embodiments of the electronic device is to include the heat storage member, the thermal conduction material which is disposed on the heat storage member, and the heat generating body which is disposed on the surface side of the thermal conduction material opposite to the heat storage member.

In a case in which the heat storage member includes the protective layer, one of the suitable embodiments of the electronic device according to the present disclosure is to include the heat storage member, a metal plate which is disposed on a surface side of the heat storage member opposite to the protective layer, and the heat generating body which is disposed on a surface side of the metal plate opposite to the heat storage member. Stated another way, it is preferable that the protective layer, the heat storage sheet, the metal plate, and the heat generating body be stacked in this order.

The heat storage members (heat storage sheet and protective layer) are as described above.

[Heat Generating Body]

The heat generating body is a member which may generate heat in the electronic device, and is, for example, systems on a chip (SoC) such as a central processing unit (CPU), a graphics processing unit (GPU), a static random access memory (SRAM), and a radio frequency (RF) device, a camera, a LED package, power electronics, and a battery (in particular, lithium-ion secondary battery).

The heat generating body may be disposed so as to be in contact with the heat storage member, or may be disposed on the heat storage member via another layer (for example, the thermal conduction material which will be described below).

[Thermal Conduction Material]

It is preferable that the electronic device further include the thermal conduction material.

The thermal conduction material has a function of conducting heat which is generated from the heat generating body to another medium.

As the “thermal conductivity” of the thermal conduction material, it is preferable that the thermal conductivity of the material be 10 Wm⁻¹K⁻¹ or more. The thermal conductivity (unit: Wm⁻¹K⁻¹) is a value measured by a flash method at a temperature of 25° C. by a method compliant with Japanese Industrial Standards (JIS) R1611.

Examples of the thermal conduction material include the metal plate, the heat radiation sheet, silicone grease, and the like, and the metal plate or the heat radiation sheet is preferable.

—Metal Plate—

The metal plate has a function of protecting the heat generating body and conducting heat which is generated from the heat generating body to the heat storage sheet.

The surface of the metal plate opposite to the surface on which the heat generating body is provided may be in contact with the heat storage sheet, or the heat storage sheet may be disposed via another layer (for example, the heat radiation sheet, the adhesion layer, or the base material).

Examples of the material configuring the metal plate include aluminum, copper, and stainless steel.

—Heat Radiation Sheet—

The heat radiation sheet is a sheet which has a function of conducting heat which is generated from the heat generating body to another medium, and it is preferable that a heat radiation material be provided. Examples of the heat radiation material include carbon, metal (for example, silver, copper, aluminum, iron, platinum, stainless steel, nickel), silicone, and the like.

Specific examples of the heat radiation sheet include a copper foil sheet, a metal film resin sheet, a metal-containing resin sheet, and a graphene sheet, and the graphene sheet is preferably used. The thickness of the heat radiation sheet is not particularly limited, but it is preferably 10 to 500 μm, and more preferably 20 to 300 μm.

[Other Members]

The electronic device may include members other than the protective layer, the heat storage sheet, the metal plate, and the heat generating body. Examples of other members include the heat radiation sheet, the base material, and the adhesion layer. The base material and the adhesion layer are as described above.

The electronic device may have at least one member selected from the group consisting of the heat radiation sheet, the base material, and the adhesion layer between the heat storage sheet and the metal plate. In a case in which two or more members among the heat radiation sheet, the base material, and the adhesion layer are disposed between the heat storage sheet and the metal plate, the base material, the adhesion layer, and the heat radiation sheet are preferably disposed in this order from the heat storage sheet side to the metal plate side.

Further, the electronic device may have the heat radiation sheet between the metal plate and the heat generating body.

### EXAMPLES

Hereinafter, the present invention will be described in more detail with reference to Examples. However, the present invention is not limited to the following Examples as long as the gist of the present invention is not exceeded. Unless otherwise noted, “parts” and “%” are based on mass.

The particle diameter D50 and a wall thickness of the microcapsule were measured by the method described above.

### Examples 1 and 2

—Preparation of Microcapsule Dispersion Liquid—

A solution A was obtained by heating and dissolving 100 parts by mass of hexadecane (latent heat storage material; an aliphatic hydrocarbon having a melting point of 18° C. and 16 carbon atoms) at 60° C.

Next, a solution B was obtained by adding 1 part by mass of propylene oxide adduct (N,N,N′,N′-tetrakis(2-hydroxypropyl)ethylenediamine, Adeka Polyether EDP-300, manufactured by ADEKA CORPORATION) of ethylenediamine dissolved in 1 part by mass of ethyl acetate to the solution A being stirred. Further, a solution C was obtained by adding 10 parts by mass of trimethylolpropane adduct (Burnock D-750, manufactured by DIC Corporation) of tolylene diisocyanate dissolved in 3 parts by mass of methyl ethyl ketone to the solution B being stirred.

Then, the solution C was added to a solution obtained by dissolving 6 parts by mass of polyvinyl alcohol (Kuraray Poval (registered trademark) PVA-217E (manufactured by Kuraray Co., Ltd., degree of polymerization 1700; PVA) as the emulsifier in 150 parts by mass of water, and the mixture was emulsified and dispersed. 300 parts by mass of water were added to the emulsified liquid after emulsification and dispersion, the mixture was heated to 70° C. with stirring, and then cooled to 30° C. after continuing stirring for 1 hour. Water was further added to the cooled liquid to adjust the concentration, and a hexadecane encapsulating microcapsule dispersion liquid which has a polyurethane urea capsule wall was obtained.

A concentration of solid contents of the hexadecane encapsulating microcapsule dispersion liquid was 21% by mass.

The mass of the capsule wall of the hexadecane encapsulating microcapsule to the mass of the encapsulated hexadecane was 11% by mass.

The obtained hexadecane encapsulating microcapsule dispersion liquid was defined as a microcapsule liquid 1. The volume-based median diameter D50 of the microcapsule in the microcapsule liquid 1 was 15 μm.

The hexadecane encapsulating microcapsule dispersion liquid which was obtained as above was mixed with 3 parts by mass of carbon black (Denka Black (registered trademark), manufactured by Denka Company Limited; thermal conductive material) to obtain a microcapsule liquid 2.

—Manufacturing of Heat Storage Sheet and Heat Storage Member—

The microcapsule liquid 1 or the microcapsule liquid 2 which was obtained as above was respectively applied on a PET base material which has a thickness of 5 μm with a bar coater such that the mass after drying is 100 g/m², and dried to manufacture heat storage members 1 and 2 including a heat storage sheet 1 or a heat storage sheet 2 on the PET base material.

The heat storage sheet 1 and the heat storage sheet 2 were obtained by peeling off each PET base material of the manufactured heat storage members 1 and 2.

In the above procedure, the heat storage sheet was manufactured by using the dispersion liquid without substantially adding the binder to the dispersion liquid.

The content ratios of hexadecane (latent heat storage material) in the obtained heat storage sheet 1 and heat storage sheet 2 to the total mass of each heat storage sheet were 85% by mass and 83% by mass, respectively. Further, the content ratios of microcapsule in the obtained heat storage sheet 1 and heat storage sheet 2 to the total mass of each heat storage sheet were 95% by mass and 92.5% by mass, respectively.

Further, the content ratio of the carbon black in the obtained heat storage sheet 2 to the total mass of the heat storage sheet was 2.5% by mass.

Further, the heat storage sheet 1 and the heat storage sheet 2 each include polyvinyl alcohol as the binder. The polyvinyl alcohol is a compound used as the emulsifier. The content ratios of polyvinyl alcohol in the obtained heat storage sheet 1 and heat storage sheet 2 to the total mass of each heat storage sheet were 5% by mass and 5% by mass, respectively.

—Measurement of Latent Heat Capacity—

The latent heat capacities of the heat storage sheet 1 and the heat storage sheet 2 which were obtained as above were calculated from the result of the differential scanning calorimetry (DSC) and the thickness of the heat storage sheet, respectively.

As a result, the latent heat capacities of the obtained heat storage sheet 1 and heat storage sheet 2 were 155 J/ml (197 J/g) and 150 J/ml (190 J/g), respectively.

Further, the obtained heat storage sheets were attached to another separately prepared base material and used as the heat storage member.

### Examples 3 and 4

—Preparation of Microcapsule Dispersion Liquid—

A solution A2 to which 120 parts by mass of ethyl acetate were added was obtained by heating and dissolving 100 parts by mass of icosane (latent heat storage material; an aliphatic hydrocarbon having a melting point of 37° C. and 20 carbon atoms) at 60° C.

Next, a solution B2 was obtained by adding 0.1 part by mass of N,N,N′,N′-tetrakis(2-hydroxypropyl)ethylenediamine (Adeka Polyether EDP-300, manufactured by ADEKA CORPORATION) to the solution A2 being stirred. Further, a solution C2 was obtained by adding 10 parts by mass of trimethylolpropane adduct (Burnock D-750, manufactured by DIC Corporation) of tolylene diisocyanate dissolved in 1 part by mass of methyl ethyl ketone to the solution B2 being stirred.

Then, the solution C2 was added to a solution obtained by dissolving 10 parts by mass of polyvinyl alcohol (Kuraray Poval (registered trademark) KL-318 (manufactured by Kuraray Co., Ltd.; PVA) as the emulsifier in 140 parts by mass of water, and the mixture was emulsified and dispersed. 250 parts by mass of water were added to the emulsified liquid after emulsification and dispersion, the mixture was heated to 70° C. with stirring, and then cooled to 30° C. after continuing stirring for 1 hour. Water was further added to the cooled liquid to adjust the concentration, and an icosane encapsulating microcapsule dispersion liquid which has a polyurethane urea capsule wall was obtained.

A concentration of solid contents of the icosane encapsulating microcapsule dispersion liquid was 19% by mass.

The mass of the capsule wall of the icosane encapsulating microcapsule to the mass of the encapsulated icosane was 10% by mass.

The obtained icosane encapsulating microcapsule liquid dispersion liquid was defined as a microcapsule liquid 3. The volume-based median diameter D50 of the microcapsule was 20 μm.

Next, a microcapsule dispersion liquid 3 was mixed with 3 parts by mass of carbon black (Denka Black (registered trademark), manufactured by Denka Company Limited; thermal conductive material) to prepare a microcapsule liquid 4.

—Manufacturing of Heat Storage Sheet and Heat Storage Member—

The obtained microcapsule liquid 3 or microcapsule liquid 4 was respectively applied on one surface of the PET base material (GL-10, manufactured by Nichieikako, Co., Ltd.) which includes the pressure sensitive adhesive layer and the peeling film on the other surface with a bar coater such that the mass after drying is 200 g/m², and dried to manufacture heat storage members 3 and 4 including a heat storage sheet 3 or a heat storage sheet 4 on the PET base material.

The heat storage sheet 3 and the heat storage sheet 4 were obtained by peeling off each PET base material of the manufactured heat storage members 3 and 4.

—Measurement of Latent Heat Capacity—

The latent heat capacities of the heat storage sheet 3, the heat storage sheet 4, the heat storage member 3, and heat storage member 4 which were obtained were calculated from the result of the differential scanning calorimetry (DSC) and the thicknesses of the heat storage sheet and the heat storage member.

The results are shown in the table, which will be described below.

Further, the obtained heat storage members were attached to another separately prepared base material and used.

### Examples 5 and 6

The icosane encapsulating microcapsule dispersion liquid was prepared in the same manner as in Example 3 except that an amount of icosane was changed from 100 parts by mass to 72 parts by mass, an amount of N,N,N′,N′-tetrakis(2-hydroxypropyl)ethylenediamine (Adeka Polyether EDP-300) was changed from 0.1 part by mass to 0.05 part by mass, an amount of Burnock D-750 (trimethylolpropane adduct of tolylene diisocyanate) was changed from 10 parts by mass to 4.0 parts by mass, and an amount of polyvinyl alcohol (Kuraray Poval KL-318) was changed from 10 parts by mass to 7.4 parts by mass in Example 3.

In this case, the concentration of solid contents of the icosane encapsulating microcapsule dispersion liquid was 14% by mass.

The mass of the capsule wall of the icosane encapsulating microcapsule to the mass of the encapsulated icosane was 6% by mass.

The obtained microcapsule liquid dispersion liquid was defined as a microcapsule liquid 5. The volume-based median diameter D50 of the microcapsule was 20 μm.

Next, a microcapsule dispersion liquid 5 was mixed with 3 parts by mass of carbon black (Denka Black (registered trademark), manufactured by Denka Company Limited; thermal conductive material) to prepare a microcapsule liquid 6.

—Manufacturing of Heat Storage Sheet and Heat Storage Member—

By adding 1.5 parts by mass of a side chain alkylbenzene sulfonic acid amine salt (NEOGEN T, manufactured by DKS Co., Ltd.), 0.15 part by mass of sodium=bis(3,3,4,4,5,5,6,6,6-nonafluorohexyl)=2-sulfinatooxysuccinate (W-AHE, manufactured by FUJIFILM Corporation), and 0.15 part by mass of polyoxyalkylene alkyl ether (Noigen LP-90, manufactured by DKS Co., Ltd.) based on 1000 parts by mass, the obtained microcapsule liquid 5 or microcapsule liquid 6 was respectively applied on one surface of the PET base material (GL-10, manufactured by Nichieikako, Co., Ltd.) which includes the pressure sensitive adhesive layer and the peeling film on the other surface with a bar coater such that the mass after drying was 133 g/m², and dried to manufacture heat storage members 5 and 6 including a heat storage sheet 5 or a heat storage sheet 6 on the PET base material.

The heat storage sheet 5 and the heat storage sheet 6 were obtained by peeling off each PET base material of the manufactured heat storage members 5 and 6.

—Measurement of Latent Heat Capacity—

The latent heat capacities of the heat storage sheet 5, the heat storage sheet 6, the heat storage member 5, and heat storage member 6 which were obtained were calculated from the result of the differential scanning calorimetry (DSC) and the thickness of the heat storage sheet.

The results are shown in the table, which will be described below.

Further, the obtained heat storage members were attached to another separately prepared base material and used.

### Example 7

A microcapsule liquid 7 was obtained by adding a solution, which was obtained by dissolving 3.8 parts by mass of polybutylstyrene rubber in 30 parts by mass of methyl ethyl ketone, to the microcapsule liquid 5 obtained in Example 5. The volume-based median diameter D50 of the microcapsule was 20 μm.

The mass of the capsule wall of the icosane encapsulating microcapsule to the mass of the encapsulated icosane was 6% by mass.

—Manufacturing of Heat Storage Sheet and Heat Storage Member—

The obtained microcapsule liquid 7 was applied on one surface of the PET base material (GL-10, manufactured by Nichieikako, Co., Ltd.) which includes the pressure sensitive adhesive layer and the peeling film on the other surface with a bar coater such that the mass after drying was 133 g/m², and dried to manufacture a heat storage member 7 including a heat storage sheet 7 on the PET base material.

The heat storage sheet 7 was obtained by peeling off each PET base material of the manufactured heat storage member 7.

—Measurement of Latent Heat Capacity—

The latent heat capacities of the heat storage sheet 7 and heat storage member 7 which were obtained were calculated from the result of the differential scanning calorimetry (DSC) and the thickness of the heat storage sheet. The results are shown in the table, which will be described below.

The obtained heat storage member 7 attached to another separately prepared base material and used.

### Comparative Examples 1 and 2

The microcapsule liquid was prepared in the same manner as in Example 3 except that an amount of icosane was changed from 100 parts by mass to 75 parts by mass, an amount of N,N,N′,N′-tetrakis(2-hydroxypropyl)ethylenediamine (Adeka Polyether EDP-300) was changed from 0.1 part by mass to 0.31 part by mass, an amount of Burnock D-750 (trimethylolpropane adduct of tolylene diisocyanate) was changed from 10 parts by mass to 24.7 parts by mass, and an amount of polyvinyl alcohol (Kuraray Poval KL-318) was changed from 10 parts by mass to 40 parts by mass in Example 3.

In this case, the concentration of solid contents of the icosane encapsulating microcapsule dispersion liquid was 22% by mass.

The mass of the capsule wall of the icosane encapsulating microcapsule to the mass of the encapsulated icosane was 33% by mass.

The obtained microcapsule liquid dispersion liquid was defined as a microcapsule liquid C1. The volume-based median diameter D50 of the microcapsule was 20 μm.

Next, a microcapsule dispersion liquid C1 was mixed with 3 parts by mass of carbon black (Denka Black (registered trademark), manufactured by Denka Company Limited) to prepare a microcapsule liquid C2.

—Manufacturing of Heat Storage Sheet and Heat Storage Member—

The obtained microcapsule liquid C1 or microcapsule liquid C2 was prepared in the same manner as in Example 5, and respectively applied on one surface of the PET base material (GL-10, manufactured by Nichieikako, Co., Ltd.) which includes the pressure sensitive adhesive layer and the peeling film on the other surface with a bar coater such that the mass after drying was 133 g/m², and dried to manufacture heat storage members C1 and C2 including a heat storage sheet C1 or a heat storage sheet C2 on the PET base material.

The heat storage sheet C1 and the heat storage sheet C2 were obtained by peeling off each PET base material of the manufactured heat storage members C1 and C2.

—Measurement of Latent Heat Capacity—

The latent heat capacities of the heat storage sheet C1, the heat storage sheet C2, the heat storage member C1, and heat storage member C2 which were obtained were calculated from the result of the differential scanning calorimetry (DSC) and the thickness of the heat storage sheet. The results are shown in the table, which will be described below.

Further, the obtained heat storage members were attached to another separately prepared base material and used.

### Comparative Example 3

Based on the method disclosed in paragraphs 0020 to 0021 of JP2001-200247A, icosane was used as the heat storage material and 40% by mass of the concentration of solid contents of microcapsule dispersion liquid including the microcapsules (particle diameter of 3 μm) in which the capsule wall material is a melamine resin was prepared to produce a microcapsule liquid C3 consisting of 100 parts by mass of the prepared microcapsule dispersion liquid and 20 parts by mass of an acrylic-styrene binder. A concentration of solid contents of the microcapsule dispersion liquid was 50% by mass.

The mass of the capsule wall of the microcapsule to the mass of the encapsulated icosane was 22% by mass.

The obtained microcapsule liquid C3 was applied on one surface of the PET base material (GL-10, manufactured by Nichieikako, Co., Ltd.) which includes the pressure sensitive adhesive layer and the peeling film on the other surface with a bar coater such that the mass after drying was 133 g/m², and dried to manufacture a heat storage member C3 including a heat storage sheet C3 on the PET base material.

The heat storage sheet C3 was obtained by peeling off each PET base material of the manufactured heat storage member C3.

—Measurement of Latent Heat Capacity—

The latent heat capacity of the heat storage sheet C3 which was obtained was calculated from the result of the differential scanning calorimetry (DSC) and the thickness of the heat storage sheet. The results are shown in the table, which will be described below.

Further, the obtained heat storage members were attached to another separately prepared base material and used.

In the table which will be described below, “content ratio (% by volume) of microcapsule” represents the content ratio (% by volume) of microcapsule to the total mass of the heat storage sheet.

In the table which will be described below, “content ratio (% by mass) of microcapsule” represents the content ratio (% by mass) of microcapsule to the total mass of the heat storage sheet.

In the table which will be described below, “carbon black (% by mass)” represents the content ratio (% by mass) of carbon black to the total mass of the heat storage sheet.

In the table which will be described below, “others (% by mass)” represents the content ratio (% by mass) of the components other than the microcapsule, the binder, and carbon black in the heat storage sheet to the total mass of the heat storage sheet.

TABLE 1

| | | | | | | | | | | | Comparative | Comparative | Comparative |
|---|---|---|---|---|---|---|---|---|---|---|---|---|---|
| | | | | Example 1 | Example 2 | Example 3 | Example 4 | Example 5 | Example 6 | Example 7 | Example 1 | Example 2 | Example 3 |
| Microcapsule liquid | | | | 1 | 2 | 3 | 4 | 5 | 6 | 7 | C1 | C2 | C3 |
| Heat | Composition | Microcapsule | Particle diameter | 15 | 15 | 20 | 20 | 20 | 20 | 20 | 20 | 20 | 3 |
| storage | | | D50 (μm) | | | | | | | | | | |
| sheet | | | Wall thickness | 0.126 | 0.126 | 0.156 | 0.156 | 0.097 | 0.097 | 0.097 | 0.404 | 0.404 | 0.045 |
| | | | (μm) | | | | | | | | | | |
| | | | Wall thickness/ | 0.008 | 0.008 | 0.008 | 0.008 | 0.005 | 0.005 | 0.005 | 0.020 | 0.020 | 0.015 |
| | | | Particle diameter | | | | | | | | | | |
| | | | Content ratio | 89 | 89 | 87 | 87 | 86 | 87 | 74 | 71 | 72 | 64 |
| | | | (% by volume) | | | | | | | | | | |
| | | | Content ratio | 95 | 92.5 | 92 | 89.5 | 90 | 87 | 87 | 71 | 69 | 67 |
| | | | (% by mass) | | | | | | | | | | |
| | | | Capsule wall | Polyurethane | Polyurethane | Polyurethane | Polyurethane | Polyurethane | Polyurethane | Polyurethane | Polyurethane | Polyurethane | Melamine |
| | | | material | urea | urea | urea | urea | urea | urea | urea | urea | urea | |
| | | Binder | Type | Water- | Water- | Water- | Water- | Water- | Water- | Oil-soluble/ | Water-soluble | Water-soluble | Oil-soluble |
| | | | | soluble | soluble | soluble | soluble | soluble | soluble | water-soluble | (dispersion) | (dispersion) | |
| | | | | (dispersion) | (dispersion) | (dispersion) | (dispersion) | (dispersion) | (dispersion) | | | | |
| | | | Content ratio | 5 | 5 | 8 | 8.1 | 9 | 8 | 13 | 28 | 28 | 33 |
| | | | (% by mass) | | | | | | | | | | |
| | | Carbon black (% by mass) | | Absence | 2.5 | Absence | 2.4 | Absence | 3.4 | Absence | Absence | 2.1 | Absence |
| | | Others (% by mass) | | Absence | Absence | Absence | Absence | 1 | 1.6 | Absence | 1 | 0.9 | Absence |
| | Physical | Content ratio of heat storage | | 85 | 83 | 83 | 81 | 85 | 82 | 83 | 53 | 52 | 55 |
| | Property | material to total mass of heat | | | | | | | | | | | |
| | | storage sheet (% by mass) | | | | | | | | | | | |
| | | Content ratio of mass of capsule | | 11 | 11 | 10 | 10 | 6 | 6 | 6 | 33 | 33 | 22 |
| | | wall to mass of heat storage | | | | | | | | | | | |
| | | material (% by mass) | | | | | | | | | | | |
| | | Encapsulation ratio of heat | | 100 | 100 | 100 | 100 | 100 | 100 | 100 | 100 | 100 | 100 |
| | | storage material in | | | | | | | | | | | |
| | | microcapsule (% by mass) | | | | | | | | | | | |
| | | Thickness (μm) | | 138 | 138 | 281 | 281 | 190 | 190 | 226 | 166 | 166 | 237 |
| | | Mass (g/m²) | | 100 | 100 | 200 | 200 | 133 | 133 | 133 | 133 | 133 | 133 |
| | | Ratio to total thickness (%) | | 97 | 97 | 97 | 97 | 95 | 95 | 96 | 94 | 94 | 96 |
| | | Void volume (% by volume) | | 7 | 7 | 7 | 7 | 7 | 7 | 16 | 7 | 7 | 10 |
| | Evaluation | Latent heat capacity (J/ml) | | 155 | 150 | 147 | 143 | 149 | 143 | 128 | 106 | 104 | 104 |
| | | Latent heat capacity (J/g) | | 197 | 190 | 190 | 183 | 194 | 185 | 182 | 122 | 119 | 125 |
| Heat | Heat storage sheet | | | 1 | 2 | 3 | 4 | 5 | 6 | 7 | C1 | C2 | C3 |
| storage | Base material | Thickness (μm) | | 5 | 5 | 10 | 10 | 10 | 10 | 10 | 10 | 10 | 10 |
| member | | Type | | PET | PET | PET 6 | PET 6 | PET 6 | PET 6 | PET 6 | PET 6 | PET 6 | PET 6 |
| | | | | | | μm/pressure | μm/pressure | μm/pressure | μm/pressure | μm/pressure | μm/pressure | μm/pressure | μm/pressure |
| | | | | | | sensitive | sensitive | sensitive | sensitive | sensitive | sensitive | sensitive | sensitive |
| | | | | | | adhesive | adhesive | adhesive | adhesive | adhesive | adhesive | adhesive | adhesive |
| | | | | | | layer 4 μm | layer 4 μm | layer 4 μm | layer 4 μm | layer 4 μm | layer 4 μm | layer 4 μm | layer 4 μm |

| | | | | | | | | | | | |
|---|---|---|---|---|---|---|---|---|---|---|---|
| Evaluation | Latent heat capacity of heat | 147 | 142 | 147 | 144 | 142 | 140 | 124 | 100 | 98 | 95 |
| | storage member (J/ml) | | | | | | | | | | |
| | Latent heat capacity of heat | 186 | 178 | 186 | 186 | 179 | 174 | 148 | 112 | 109 | 111 |
| | storage member (J/g) | | | | | | | | | | |

### Example 8

A heat storage sheet 8 was manufactured in the same manner as in Example 5 except that, instead of water for adjusting the concentration by further adding water to the cooled liquid, an aqueous solution in which 20% by mass of water and Taien E (manufactured by Taihei Chemical Industrial Co., Ltd., flame retardant) are dispersed in water was used to adjust the concentration, and the concentration was adjusted such that Taien E was 5% by mass based on the total solid content of the dispersion liquid including Taien E and icosane encapsulating microcapsule in Example 5.

### Examples 9 to 11

Heat storage sheets 9 to 11 were manufactured in the same manner as in Example 8 except that, instead of Taien E, Taien K (manufactured by Taihei Chemical Industrial Co., Ltd., flame retardant; Example 9), Taien N (manufactured by Taihei Chemical Industrial Co., Ltd., flame retardant; Example 10), and a 2:1 mixed material (Example 11) or Taien E and APA100 (manufactured by Taihei Chemical Industrial Co., Ltd., flame retardant) were used in Example 8.

### Example 12

An optical pressure sensitive adhesive sheet MO-3015 (thickness: 5 μm) manufactured by LINTEC Corporation was attached to the PET base material which has a thickness of 12 μm to form the pressure sensitive adhesive layer, an aqueous solution in which Nipol Latex LX407C4E (manufactured by Zeon Corporation), Nipol Latex LX407C4C (manufactured by Zeon Corporation), and Aquabrid EM-13 (manufactured by Daicel Fine Chem Ltd.) were mixed and dissolved such that the concentration of solid contents was 22:77.5:0.5 [mass-based] was applied on the surface of the PET base material opposite to the surface including the pressure sensitive adhesive layer, and dried at 115° C. for 2 minutes to prepare a PET base material (A) with the pressure sensitive adhesive layer which has the easily adhesive layer formed of a styrene-butadiene rubber resin which has a thickness of 1.3 μm.

A heat storage member 12 was manufactured in the same manner as in Example 5 except that the PET base material was changed to the PET base material (A) with the pressure sensitive adhesive layer in Example 5.

### Example 13

A heat storage member 13 was manufactured in the same manner as in Example 11 except that the PET base material was changed to the PET base material (A) with the pressure sensitive adhesive layer in Example 11.

### Example 14

A protective layer forming composition A was prepared by dissolving 22.3 parts by mass of pure water, 32.5 parts by mass of ethanol, 3.3 parts by mass of acetic acid, and 41.9 parts by mass of KR-516 (manufactured by Shin-Etsu Chemical Co., Ltd., siloxane oligomer) and stirring the dissolved solution for 12 hours. Next, in the heat storage member 12 which was manufactured in Example 12, the protective layer forming composition A was applied to the side of the heat storage sheet opposite to the side provided with the PET base material (A) with the pressure sensitive adhesive layer, and was dried at 100° C. for 10 minutes to form the flame retardant protective layer which has a thickness of 8 μm to manufacture a heat storage member 14.

### Example 15

A protective layer forming composition B was prepared by dissolving and dispersing 31.6 parts by mass of Epocros WS-700 (manufactured by Nippon Shokubai Co., Ltd., 25% of concentration of solid contents; hardening agent), 29.6 parts by mass of Taien E (manufactured by Taihei Chemical Industrial Co., Ltd.; flame retardant), and 3.0 parts by mass of Noigen LP-70 (manufactured by DKS Co., Ltd. (diluted in an aqueous solution which has 2% by mass of concentration of solid contents); surfactant) in 35.8 parts by mass of KYNAR Aquatec ARC (manufactured by Arkema, 44% by mass of concentration of solid contents; fluorine-containing resin).

Next, in the heat storage member 12 which was manufactured in Example 12, the protective layer forming composition B was applied to the side of the heat storage sheet opposite to the side provided with the PET base material (A) with the pressure sensitive adhesive layer, and was dried at 100° C. for 3 minutes to form the flame retardant protective layer which has a thickness of 8 μm to manufacture a heat storage member 15.

### Example 16

A protective layer forming composition C was prepared by dissolving 30.0 parts by mass of X-12-1098 (manufactured by Shin-Etsu Chemical Co., Ltd.; silane coupling agent) and 2.0 parts by mass of Noigen LP-70 (manufactured by DKS Co., Ltd. (diluted in an aqueous solution which has 2% of a concentration of solid contents); surfactant) in 68.0 parts by mass of pure water.

In the heat storage member 12 which was manufactured in Example 12, the protective layer forming composition C was applied to the side of the heat storage sheet opposite to the side provided with the PET base material (A) with the pressure sensitive adhesive layer, and was dried at 100° C. for 3 minutes to form the flame retardant protective layer which has a thickness of 1 μm to manufacture a heat storage member 16.

### Example 17

30.0 parts by mass of X-12-1098 (manufactured by Shin-Etsu Chemical Co., Ltd.) and 2.0 parts by mass of Noigen LP-70 (manufactured by DKS Co., Ltd. (used by being diluted in 2% by mass the concentration of solid contents); surfactant) were dissolved in 68.0 parts by mass of pure water, and then 1 mol/L of sodium hydroxide aqueous solution was added to adjust pH to 9.0, and the mixture was stirred for 1 hour. Then, 1 mol/L of hydrochloric acid water was added to adjust the pH to 3.2 to prepare a protective layer forming composition D.

In the heat storage member 12 which was manufactured in Example 12, the protective layer forming composition D was applied to the side of the heat storage sheet opposite to the side provided with the PET base material (A) with the pressure sensitive adhesive layer, and was dried at 100° C. for 3 minutes to form the flame retardant protective layer which has a thickness of 3 μm to manufacture a heat storage member 17.

### Example 18

A heat storage member 18 was manufactured in the same manner as in Example 15 except that the flame retardant protective layer was 2 μm.

### Example 19

A heat storage member 19 was manufactured in the same manner as in Example 15 except that the flame retardant protective layer was 5 μm.

### Example 20

A heat storage member 20 was manufactured in the same manner as in Example 15 except that the flame retardant protective layer was 15 μm.

### Example 21

A protective layer forming composition E was prepared by dissolving 0.4 part by mass of acetic acid, 27.0 parts by mass of X-12-1098 (manufactured by Shin-Etsu Chemical Co., Ltd.), 3.0 parts by mass of KBE-04 (manufactured by Shin-Etsu Chemical Co., Ltd.; silane coupling agent) and 1.5 parts by mass of Noigen LP-70 (manufactured by DKS Co., Ltd. (used by being diluted in 2% by mass of concentration of solid contents); surfactant) in 68.1 parts by mass of pure water, and stirring the dissolved solution for 2 hours. In the heat storage member which was manufactured in Example 12, the protective layer forming composition E was applied to the surface of the heat storage sheet opposite to the PET base material (A) with the pressure sensitive adhesive layer, and was dried at 100° C. for 3 minutes to form the flame retardant protective layer which has a thickness of 3 μm to manufacture a heat storage member 21.

### Example 22

A heat storage member 22 was manufactured in the same manner as in Example 21 except that the protective layer was 6 μm.

### Example 23

A protective layer forming composition F was prepared by dissolving 0.4 part by mass of acetic acid, 24.0 parts by mass of X-12-1098 (manufactured by Shin-Etsu Chemical Co., Ltd.), 6.0 parts by mass of KBE-04 (manufactured by Shin-Etsu Chemical Co., Ltd.; silane coupling agent) and 1.5 parts by mass of Noigen LP-70 (manufactured by DKS Co., Ltd. (used by being diluted in 2% by mass of concentration of solid contents); surfactant) in 68.1 parts by mass of pure water, and stirring the dissolved solution for 2 hours. In the heat storage member which was manufactured in Example 12, the protective layer forming composition F was applied to the surface of the heat storage sheet opposite to the surface including the PET base material (A) with the pressure sensitive adhesive layer, and was dried at 100° C. for 3 minutes to form the flame retardant protective layer which has a thickness of 3 μm to manufacture a heat storage member 23.

### Example 24

A heat storage member 24 was manufactured in the same manner as in Example 23 except that the flame retardant protective layer was 6 μm.

### Example 25

A protective layer forming composition G was prepared by dissolving 0.4 part by mass of acetic acid, 21.0 parts by mass of X-12-1098 (manufactured by Shin-Etsu Chemical Co., Ltd.), 9.0 parts by mass of KBE-04 (manufactured by Shin-Etsu Chemical Co., Ltd.; silane coupling agent) and 1.5 parts by mass of Noigen LP-70 (manufactured by DKS Co., Ltd. (used by being diluted in 2% by mass of concentration of solid contents); surfactant) in 68.1 parts by mass of pure water, and stirring the dissolved solution for 2 hours. In the heat storage member which was manufactured in Example 12, the protective layer forming composition G was applied to the surface of the heat storage sheet opposite to the surface including the PET base material (A) with the pressure sensitive adhesive layer, and was dried at 100° C. for 3 minutes to form the flame retardant protective layer which has a thickness of 3 μm to manufacture a heat storage member 25.

### Example 26

A heat storage member 26 was manufactured in the same manner as in Example 25 except that the flame retardant protective layer was 6 μm.

### Example 27

A protective layer forming composition H was prepared by dissolving 0.4 part by mass of acetic acid, 15.0 parts by mass of X-12-1098 (manufactured by Shin-Etsu Chemical Co., Ltd.), 15.0 parts by mass of KBE-04 (manufactured by Shin-Etsu Chemical Co., Ltd.; silane coupling agent) and 1.5 parts by mass of Noigen LP-70 (manufactured by DKS Co., Ltd. (used by being diluted in 2% by mass of concentration of solid contents); surfactant) in 68.1 parts by mass of pure water, and stirring the dissolved solution for 2 hours. In the heat storage member which was manufactured in Example 12, the protective layer forming composition H was applied to the surface of the heat storage sheet opposite to the surface including the PET base material (A) with the pressure sensitive adhesive layer, and was dried at 100° C. for 3 minutes to form the flame retardant protective layer which has a thickness of 3 μm to manufacture a heat storage member 27.

### Example 28

A heat storage member 28 was manufactured in the same manner as in Example 27 except that the flame retardant protective layer was 6 μm.

### Example 29

After 0.4 part by mass of acetic acid, 24.0 parts by mass of X-12-1098 (manufactured by Shin-Etsu Chemical Co., Ltd.), 6.0 parts by mass of KBE-04 (manufactured by Shin-Etsu Chemical Co., Ltd.; silane coupling agent) and 1.5 parts by mass of Noigen LP-70 (manufactured by DKS Co., Ltd. (used by being diluted in 2% by mass of concentration of solid contents); surfactant) were dissolved in 68.1 parts by mass of pure water, the dissolved solution was stirred for 2 hours to prepare a liquid J, and a coating liquid prepared by mixing 8 parts by mass of pure water, 67 parts by mass of the liquid J, and 25 parts by mass of Snowtex OYL (manufactured by Nissan Chemical Corporation, silica particle) was defined as a protective layer forming composition K. In the heat storage member which was manufactured in Example 12, the protective layer forming composition K was applied to the surface of the heat storage sheet opposite to the surface including the PET base material (A) with the pressure sensitive adhesive layer, and was dried at 100° C. for 3 minutes to form the flame retardant protective layer which has a thickness of 3 μm to manufacture a heat storage member 29.

### Example 30

A heat storage member 30 was manufactured in the same manner as in Example 29 except that the flame retardant protective layer was 6 μm.

For the heat storage members 5 and 8 to 30 and Comparative Examples 1 to 3, the flame retardance, the pressure sensitive adhesive strength, and the amount of heat storage of the heat storage member were evaluated.

(Flame Retardance)

A test was performed based on UL94HB standard (Underwriters Laboratories Inc.) except that the peeling films of the heat storage members 5 and 8 to 30 were peeled off, the surface on the pressure sensitive adhesive layer side was attached to an aluminum plate which has a thickness of 0.3 mm, and the flame was contacted from the heat storage member side, and the pass and failure were determined.

In Tables 2 to 5, “Pass” indicates a pass and “Fail” indicates a failure.

(Adhesion (Pressure Sensitive Adhesive Strength))

The peeling films of the heat storage members 5 and 8 to 30 were peeled off, the surface on the pressure sensitive adhesive layer side was attached to SUS304, and the adhesion to the SUS304 base material was measured under the condition of 1 minute after attachment, 180° of peeling, 300 mm/min according to the Japanese Industrial Standards (JIS)-Z0237.

TABLE 2

| | | | | Example | Example | Example | Example | Example | Example | Example |
|---|---|---|---|---|---|---|---|---|---|---|
| | | | | 5 | 8 | 9 | 10 | 11 | 12 | 13 |
| Microcapsule liquid | | | | 5 | 8 | 9 | 10 | 11 | 5 | 11 |
| Heat | Compo- | Micro- | Particle | 20 | 20 | 20 | 20 | 20 | 20 | 20 |
| storage | sition | capsule | diameter | | | | | | | |
| sheet | | | D50 (μm) | | | | | | | |
| | | | Wall | 0.097 | 0.097 | 0.097 | 0.097 | 0.097 | 0.097 | 0.097 |
| | | | thickness | | | | | | | |
| | | | (μm) | | | | | | | |
| | | | Wall | 0.005 | 0.005 | 0.005 | 0.005 | 0.005 | 0.005 | 0.005 |
| | | | thickness/ | | | | | | | |
| | | | Particle | | | | | | | |
| | | | diameter | | | | | | | |
| | | | Content | 86 | 87 | 87 | 87 | 87 | 86 | 87 |
| | | | ratio (% by | | | | | | | |
| | | | volume) | | | | | | | |
| | | | Content | 90 | 86 | 86 | 86 | 86 | 90 | 86 |
| | | | ratio (% | | | | | | | |
| | | | by mass) | | | | | | | |
| | | | Capsule | Poly- | Poly- | Poly- | Poly- | Poly- | Poly- | Poly- |
| | | | wall | urethane | urethane | urethane | urethane | urethane | urethane | urethane |
| | | | material | urea | urea | urea | urea | urea | urea | urea |
| | | Binder | Type | Water- | Water- | Water- | Water- | Water- | Water- | Water- |
| | | | | soluble | soluble | soluble | soluble | soluble | soluble | soluble |
| | | | | (resolution) | (resolution) | (resolution) | (resolution) | (resolution) | (resolution) | (resolution) |
| | | | Content | 9 | 8 | 8 | 8 | 8 | 9 | 8 |
| | | | ratio (% | | | | | | | |
| | | | by mass) | | | | | | | |
| | | Flame | | Absence | Taien E | Taien K | Taien N | (Taien E: | Absence | (Taien E: |
| | | retardant | | | 5% | 5% | 5% | APA100 = | | APA100 = |
| | | | | | | | | 2:1) 5% | | 2:1) 5% |
| | | Carbon black | | Absence | Absence | Absence | Absence | Absence | Absence | Absence |
| | | (% by mass) | | | | | | | | |
| | | Others (% by mass) | | 1 | 1 | 1 | 1 | 1 | 1 | 1 |
| | Physical | Content ratio of heat | | 85 | 81 | 81 | 81 | 81 | 85 | 81 |
| | Property | storage material to | | | | | | | | |
| | | total mass of heat | | | | | | | | |
| | | storage sheet | | | | | | | | |
| | | (% by mass) | | | | | | | | |
| | | Content ratio of | | 6 | 6 | 6 | 6 | 6 | 6 | 6 |
| | | mass of capsule | | | | | | | | |
| | | wall to mass of | | | | | | | | |
| | | heat storage material | | | | | | | | |
| | | (% by mass) | | | | | | | | |
| | | Encapsulation | | 100 | 100 | 100 | 100 | 100 | 100 | 100 |
| | | ratio of heat | | | | | | | | |
| | | storage material | | | | | | | | |
| | | in microcapsule | | | | | | | | |
| | | (% by mass) | | | | | | | | |
| | | Thickness (μm) | | 190 | 190 | 190 | 190 | 190 | 190 | 190 |
| | | Mass (g/m²) | | 133 | 133 | 133 | 133 | 133 | 133 | 133 |
| | | Ratio to total | | 95 | 95 | 95 | 95 | 95 | 92 | 92 |
| | | thickness (%) | | | | | | | | |
| | | Void volume | | 7 | 7 | 7 | 7 | 7 | 7 | 7 |
| | | (% by volume) | | | | | | | | |
| | Evaluation | Latent heat capacity | | 149 | 142 | 143 | 141 | 142 | 149 | 142 |
| | | (J/ml) | | | | | | | | |
| | | Latent heat capacity | | 194 | 182 | 181 | 182 | 183 | 194 | 183 |
| | | (J/g) | | | | | | | | |
| Heat | Heat storage sheet | | | 5 | 8 | 9 | 10 | 11 | 12 | 13 |
| storage | Easily adhesive layer | | | Absence | Absence | Absence | Absence | Absence | Presence | Presence |
| member | Base | Thickness (μm) | | 10 | 10 | 10 | 10 | 10 | 17 | 17 |
| | material | Type | | GL-10 | GL-10 | GL-10 | GL-10 | GL-10 | PET base | PET base |
| | | | | | | | | | material | material |
| | | | | | | | | | (A) with | (A) with |
| | | | | | | | | | pressure | pressure |
| | | | | | | | | | sensitive | sensitive |
| | | | | | | | | | adhesive | adhesive |
| | | | | | | | | | layer | layer |

| | | | | | | | | |
|---|---|---|---|---|---|---|---|---|
| Evaluation | Latent heat capacity | 142 | 135 | 134 | 133 | 136 | 136 | 129 |
| | of heat storage | | | | | | | |
| | member (J/ml) | | | | | | | |
| | Latent heat capacity | 179 | 167 | 166 | 165 | 168 | 166 | 155 |
| | of heat storage | | | | | | | |
| | member (J/g) | | | | | | | |
| | Flame retardance of | Fail | Pass | Pass | Pass | Pass | Fail | Pass |
| | heat storage member | | | | | | | |
| | Adhesion of heat | 0.32 | 0.33 | 0.31 | 0.32 | 0.33 | 0.55 | 0.56 |
| | storage member | | | | | | | |
| | (N/mm) | | | | | | | |

TABLE 3

| | | | Example 12 | Example 14 | Example 15 | Example 16 | Example 17 |
|---|---|---|---|---|---|---|---|
| Heat | Heat storage sheet | | 5 | 5 | 5 | 5 | 5 |
| storage | Easily adhesive layer | | Presence | Presence | Presence | Presence | Presence |
| member | Base material | | PET base material | PET base material | PET base material | PET base material | PET base material |
| | | | (A) with pressure | (A) with pressure | (A) with pressure | (A) with pressure | (A) with pressure |
| | | | sensitive adhesive | sensitive adhesive | sensitive adhesive | sensitive adhesive | sensitive adhesive |
| | | | layer | layer | layer | layer | layer |
| | Flame | Protective layer | Absence | A | B | C | D |
| | retardant | forming composition | | | | | |
| | protective | Type | | Hardening film | Hardening film | Hydrolysis | Hydrolysis |
| | layer | | | (KR516) | (KYNAR | condensate film | condensate film |
| | | | | | ARC/WS-700/ | (X-12-1098) | (X-12-1098) |
| | | | | | Taien E) | | |
| | | Thickness (μm) | | 8 | 8 | 1 | 3 |
| | Evaluation | Latent heat capacity | 136 | 130 | 132 | 135 | 133 |
| | | of heat storage | | | | | |
| | | member (J/ml) | | | | | |
| | | Latent heat capacity | 166 | 154 | 156 | 164 | 161 |
| | | of heat storage | | | | | |
| | | member (J/g) | | | | | |
| | | Flame retardance of | Fail | Pass | Pass | Pass | Pass |
| | | heat storage member | | | | | |
| | | Adhesion of heat | 0.55 | 0.57 | 0.57 | 0.55 | 0.56 |
| | | storage member | | | | | |
| | | (N/mm) | | | | | |

TABLE 4

| | | | Example 18 | Example 19 | Example 20 | Example 21 | Example 22 | Example 23 | Example 24 |
|---|---|---|---|---|---|---|---|---|---|
| Heat | Heat storage sheet | | 5 | 5 | 5 | 5 | 5 | 5 | 5 |
| storage | Easily adhesive layer | | Presence | Presence | Presence | Presence | Presence | Presence | Presence |
| member | Base material | | PET base | PET base | PET base | PET base | PET base | PET base | PET base |
| | | | material | material | material | material | material | material | material |
| | | | (A) with | (A) with | (A) with | (A) with | (A) with | (A) with | (A) with |
| | | | pressure | pressure | pressure | pressure | pressure | pressure | pressure |
| | | | sensitive | sensitive | sensitive | sensitive | sensitive | sensitive | sensitive |
| | | | adhesive | adhesive | adhesive | adhesive | adhesive | adhesive | adhesive |
| | | | layer | layer | layer | layer | layer | layer | layer |
| | Flame | Protective film | B | B | B | E | E | F | F |
| | retardant | forming composition | | | | | | | |
| | protective | Type | Hardening film (KYNAR | | | Hydrolysis condensate | | Hydrolysis condensate | |
| | layer | | ARC/WS-700/Taien E) | | | film | | film | |
| | | | | | | (X-12-1098/KBE-04 = | | (X-12-1098/KBE-04 = | |
| | | | | | | 9/1) | | 8/2) | |
| | | Thickness (μm) | 2 | 5 | 15 | 3 | 6 | 3 | 6 |
| | Evaluation | Latent heat capacity | 134 | 132 | 124 | 134 | 131 | 134 | 132 |
| | | of heat storage | | | | | | | |
| | | member (J/ml) | | | | | | | |
| | | Latent heat capacity | 163 | 159 | 145 | 162 | 157 | 162 | 158 |
| | | of heat storage | | | | | | | |
| | | member (J/g) | | | | | | | |
| | | Flame retardance of | Pass | Pass | Pass | Pass | Pass | Pass | Pass |
| | | heat storage member | | | | | | | |
| | | Adhesion of heat | 0.57 | 0.59 | 0.65 | 0.60 | 0.65 | 0.61 | 0.66 |
| | | storage member | | | | | | | |
| | | (N/mm) | | | | | | | |

TABLE 5

| | | | Example | Example | Example | Example | Example | Example |
|---|---|---|---|---|---|---|---|---|
| | | | 25 | 26 | 27 | 28 | 29 | 30 |
| Heat | Heat storage sheet | | 5 | 5 | 5 | 5 | 5 | 5 |
| storage | Easily adhesive layer | | Presence | Presence | Presence | Presence | Presence | Presence |
| member | Base material | | PET base | PET base | PET base | PET base | PET base | PET base |
| | | | material | material | material | material | material | material |
| | | | (A) with | (A) with | (A) with | (A) with | (A) with | (A) with |
| | | | pressure | pressure | pressure | pressure | pressure | pressure |
| | | | sensitive | sensitive | sensitive | sensitive | sensitive | sensitive |
| | | | adhesive | adhesive | adhesive | adhesive | adhesive | adhesive |
| | | | layer | layer | layer | layer | layer | layer |
| | Flame | Protective film forming composition | G | G | H | H | K | K |
| | retardant | Type | Hydrolysis | | Hydrolysis | | Hydrolysis | |
| | protective | | condensate film | | condensate film | | condensate film | |
| | layer | | (X-12-1098/ | | (X-12-1098/ | | (X-12-1098/ | |
| | | | KBE-04 = 7/3) | | KBE-04 = 5/5) | | KBE-04 = 8/2, | |
| | | | | | | | silica particle) | |
| | | Thickness (μm) | 3 | 6 | 3 | 6 | 3 | 6 |
| | Evaluation | Latent heat capacity of heat storage | 134 | 131 | 133 | 130 | 135 | 133 |
| | | member (J/ml) | | | | | | |
| | | Latent heat capacity of heat | 162 | 157 | 161 | 156 | 161 | 157 |
| | | storage member (J/g) | | | | | | |
| | | Flame retardance of heat storage member | Pass | Pass | Pass | Pass | Pass | Pass |
| | | Adhesion of heat storage member (N/mm) | 0.61 | 0.66 | 0.62 | 0.67 | 0.63 | 0.68 |

From Table 1, it can be seen that Examples 1 to 7 in which the content ratio of the heat storage material is 65% by mass or more are excellent in the amount of heat storage as compared with Comparative Examples 1 to 3.

From Tables 2 to 5, it can be seen that the heat storage member can be imparted with flame retardance by introducing the flame retardant and the flame retardant protective layer.

Regarding the heat storage members which were manufactured in Examples 5 and 8 to 30, in a case in which the pressure sensitive adhesive layer adjacent to the PET base material adhered to a metal cover surface of the CPU, it was confirmed that the heat storage sheet surface did not become hot even in a case in which the CPU generates heat.

Even in a case in which n-icosane is changed to each of n-heptadecane (aliphatic hydrocarbon having a melting point of 22° C. and 17 carbon atoms), n-octadecane (aliphatic hydrocarbon having a melting point of 28° C. and 18 carbon atoms), n-nonadecane (aliphatic hydrocarbon having a melting point of 32° C. and 19 carbon atoms), n-henicosane (aliphatic hydrocarbon having a melting point of 40° C. and 21 carbon atoms), n-docosane (aliphatic hydrocarbon having a melting point of 44° C. and 22 carbon atoms), n-tricosane (aliphatic hydrocarbon having a melting point of 48° C. to 50° C. and 23 carbon atoms), n-tetracosane (aliphatic hydrocarbon having a melting point of 52° C. and 24 carbon atoms), n-pentacosane (aliphatic hydrocarbon having a melting point of 53° C. to 56° C. and 25 carbon atoms), and n-hexacosane (aliphatic hydrocarbon having a melting point of 60° C. and 26 carbon atoms), the heat storage members are manufactured in the same manner as in Example 1, and the test is performed in the same manner as above, the same effects are obtained.

The heat storage sheet and the heat storage member according to the present disclosure can be used, for example, as heat storage and heat radiation members for stable operation by maintaining the surface temperature of a heat generating unit in the electronic device in any temperature range. Furthermore, it can be suitably used in applications such as building materials such as flooring materials, roofing materials, wall materials, and the like, which are suitable for temperature control to rapid temperature rise during the day or during indoor heating and cooling; clothing such as underwear, outerwear, winter clothes, gloves, and the like, which are suitable for temperature control depending on the changes in environmental temperature or changes in body temperature during exercise or rest; bedding; and an exhaust heat utilization system which stores unnecessary exhaust heat and uses it as heat energy.

What is claimed is:

1. A heat storage sheet comprising:
a heat storage material; and
a microcapsule which encapsulates at least a part of the heat storage material,
wherein a content ratio of the heat storage material to a total mass of the heat storage sheet is 65% by mass or more.

2. The heat storage sheet according to claim 1, further comprising a binder.

3. The heat storage sheet according to claim 2,
wherein the binder is a water-soluble polymer.

4. The heat storage sheet according to claim 3,
wherein the water-soluble polymer is polyvinyl alcohol.

5. The heat storage sheet according to claim 2,
wherein a content ratio of the binder to a total mass of the microcapsule is 15% by mass or less.

6. The heat storage sheet according to claim 1,
wherein a content ratio of the microcapsule to the total mass of the heat storage sheet is 75% by mass or more.

7. The heat storage sheet according to claim 1,
wherein a mass of a capsule wall of the microcapsule to a mass of the heat storage material is 12% by mass or less.

8. The heat storage sheet according to claim 1,
wherein a capsule wall of the microcapsule includes at least one selected from the group consisting of polyurethane urea, polyurethane, and polyuria.

9. The heat storage sheet according to claim 1,
wherein the microcapsule satisfies a relationship of Expression (1),
δ/Dm≤0.010 Expression (1)
where δ represents a thickness (μm) of a capsule wall of the microcapsule and Dm represents a volume-based median diameter (μm) of the microcapsule.

10. The heat storage sheet according to claim 1,
wherein the content ratio of the heat storage material to the total mass of the heat storage sheet is 80% by mass or more.

11. The heat storage sheet according to claim 1, further comprising a thermal conductive material.

12. The heat storage sheet according to claim 1,
wherein a content of a linear aliphatic hydrocarbon having a melting point of 0° C. or higher to a total mass of the heat storage material is 98% by mass or more.

13. The heat storage sheet according to claim 1,
wherein a latent heat capacity is 135 J/ml or more.

14. The heat storage sheet according to claim 1,
wherein a latent heat capacity is 160 J/g or more.

15. A heat storage member comprising:
the heat storage sheet according to claim 1; and
a base material.

16. The heat storage member according to claim 15, further comprising an adhesion layer which is provided on a side of the base material opposite to a side provided with the heat storage sheet.

17. The heat storage member according to claim 15, further comprising an easily adhesive layer which is provided between the base material and the heat storage sheet.

18. The heat storage member according to claim 15, further comprising a protective layer.

19. An electronic device comprising:
the heat storage member according to claim 15.

20. A manufacturing method of a heat storage sheet, the method comprising:
a step of mixing a heat storage material, polyisocyanate, at least one active hydrogen-containing compound selected from the group consisting of polyol and polyamine, and an emulsifier to produce a dispersion liquid including a microcapsule which encapsulates at least a part of the heat storage material; and
a step of manufacturing a heat storage sheet by using the dispersion liquid without substantially adding a binder to the dispersion liquid.

21. The manufacturing method of a heat storage sheet according to claim 20,
wherein the microcapsule satisfies a relationship of Expression (1),
δ/Dm≤0.010 Expression (1)
where δ represents a thickness (μm) of a capsule wall of the microcapsule and Dm represents a volume-based median diameter (μm) of the microcapsule.

22. The manufacturing method of a heat storage sheet according to claim 20,
wherein the emulsifier is able to be bonded to the polyisocyanate.
